(19) United States
(12) Patent Application Publication
(10) Pub. No.: US 2024/0059803 A1
(43) Pub. Date: Feb. 22, 2024

(54) PHOTOSENSITIVE RESIN MULTILAYER BODY AND METHOD FOR PRODUCING SAME

(71) Applicant: ASAHI KASEI KABUSHIKI KAISHA, Tokyo (JP)

(72) Inventors: Kazuya NAITO, Tokyo (JP); Naohiro MURATA, Tokyo (JP); Takayuki MATSUDA, Tokyo (JP)

(73) Assignee: ASAHI KASEI KABUSHIKI KAISHA, Tokyo (JP)

(21) Appl. No.: 18/280,168

(22) PCT Filed: Mar. 4, 2022
(86) PCT No.: PCT/JP2022/009513

§ 371 Date: Sep. 1, 2023

(30) Foreign Application Priority Data
Mar. 5, 2021 (JP) 2021-035496

(51) Int. Cl. C08F 2/50; C08F 220/06; C08F 220/18; C08F 222/10; C08K 5/00; C08K 5/14; C08K 5/3445; G03F 7/028; G03F 7/033; G03F 7/16; H05K 3/18

(52) U.S. Cl. CPC C08F 2/50; C08F 220/06; C08F 220/1807; C08F 222/102; C08F 222/104; C08K 5/0041; C08K 5/14; C08K 5/3445; G03F 7/028; G03F 7/033; G03F 7/16; H05K 3/18

(57) ABSTRACT

The present disclosure provides: a photosensitive resin multilayer body that has a photosensitive resin composition layer on a support film, the photosensitive resin composition layer being able to achieve a good balance among color developability upon exposure to light, solubility in a developer solution (that is developability), and colorability of a base film; and a method for producing this photosensitive resin multilayer body. This photosensitive resin multilayer body is provided with: a support film; and a photosensitive resin composition layer that is formed on the support film. The photosensitive resin composition layer contains an alkali-soluble polymer, a compound that has an ethylenically unsaturated double bond, a photopolymerization initiator, and a peroxide that contains an acetone peroxide and/or methyl ethyl ketone peroxide. The content of the peroxide in the photosensitive resin composition layer is from 0.01 ppm to 1,000 ppm based on the photosensitive resin composition layer.

### TECHNICAL FIELD

The present disclosure relates to a photosensitive resin multilayer body and a method for producing the same.

### BACKGROUND ART

Printed wiring boards are generally produced by photolithography. The photolithography is a method of forming a desired wiring pattern on a substrate through the following steps. In other words, first, a layer made of a photosensitive resin composition is formed on a substrate, and the coating film undergoes pattern exposure and development to form a resist pattern. Then, a conductor pattern is formed by etching or plating. Thereafter, a desired wiring pattern is formed on the substrate by removing the resist pattern on the substrate.

Photosensitive elements (photosensitive resin multilayer bodies) are often used in the production of printed wiring boards. There are many known examples of methods for forming wiring patterns using this photosensitive element and photosensitive resin compositions suitable therefor (PTLs 1 to 3).

### CITATION LIST

### Patent Literature

[PTL 1] WO 2012/101908 A

[PTL 2] WO 2015/174467 A

[PTL 3] WO 2015/174468 A

### SUMMARY

### Technical Problem

However, the photosensitive resin compositions mentioned in PTLs 1 to 3 still have room for improvement in color developability upon exposure, solubility in a developing solution (i.e., developability) and colorability of a support film.

Therefore, one of the objects of the present disclosure is to provide a photosensitive resin multilayer body comprising, on a support film, a photosensitive resin composition layer capable of achieving all of color developability upon exposure, solubility in a developing solution (i.e., developability) and colorability of the support film, and a method for producing the same.

### Solution to Problem

Examples of the embodiment of the present disclosure are listed in items [1] to [18] below.

[1]

A photosensitive resin multilayer body comprising a support film, and a photosensitive resin composition layer formed on the support film, wherein the photosensitive resin composition layer comprises:
an alkali-soluble polymer,
a compound having an ethylenically unsaturated double bond,
a photopolymerization initiator, and
a peroxide containing acetone peroxide and/or methyl ethyl ketone peroxide, and
the content of the peroxide in the photosensitive resin composition layer is 0.01 ppm or more and 1,000 ppm or less, based on the photosensitive resin composition layer.
   [2]

The photosensitive resin multilayer body according to item 1, wherein the content of the peroxide in the photosensitive resin composition layer is 0.1 ppm or more, based on the photosensitive resin composition layer.

[3]

The photosensitive resin multilayer body according to item 1, wherein the content of the peroxide in the photosensitive resin composition layer is 1 ppm or more, based on the photosensitive resin composition layer.

[4]

The photosensitive resin multilayer body according to item 1, wherein the content of the peroxide in the photosensitive resin composition layer is 10 ppm or more, based on the photosensitive resin composition layer.

[5 ]

The photosensitive resin multilayer body according to any one of items 1 to 4, wherein the content of the peroxide in the photosensitive resin composition layer is 200 ppm or less, based on the photosensitive resin composition layer.

[6]

The photosensitive resin multilayer body according to any one of items 1 to 4, wherein the content of the peroxide in the photosensitive resin composition layer is less than 100 ppm based on the photosensitive resin composition layer.

[7]

The photosensitive resin multilayer body according to any one of items 1 to 3, wherein the content of the peroxide in the photosensitive resin composition layer is 10 ppm or less, based on the photosensitive resin composition layer.

[8]

The photosensitive resin multilayer body according to any one of items 1 to 3, wherein the content of the peroxide in the photosensitive resin composition layer is 5 ppm or less, based on the photosensitive resin composition layer.

[9]

The photosensitive resin multilayer body according to item 1 or 2, wherein the content of the peroxide in the photosensitive resin composition layer is 1 ppm or less, based on the photosensitive resin composition layer.

[10]

The photosensitive resin multilayer body according to any one of items 1 to 9, wherein the alkali-soluble polymer is a copolymer including an aromatic component as a monomer unit.

[11]

The photosensitive resin multilayer body according to any one of items 1 to 10, wherein the compound having an ethylenically unsaturated double bond contains a monomer having three or four (meth)acryloyl groups.

[12]

The photosensitive resin multilayer body according to any one of items 1 to 11, wherein the photosensitive resin composition layer further comprises a colorant, and the colorant comprises 0.01 part by weight to 1 part by weight of a dye and 0 part by weight to 0.01 part by weight of a pigment based on 100 parts by weight of the alkali-soluble polymer.

[13]

The photosensitive resin multilayer body according to item 12, wherein the dye comprises Leuco Crystal Violet and/or Diamond Green.

[14]

The photosensitive resin multilayer body according to any one of items 1 to 13, wherein the photosensitive resin composition layer further comprises a radical polymerization inhibitor.

[15]

The photosensitive resin multilayer body according to any one of items 1 to 14, wherein the photosensitive resin composition layer comprises a colorant, and an oxide and/or a decomposition product of the colorant.

[16]

The photosensitive resin multilayer body according to item 15, comprising, as the oxide and/or the decomposition product of the colorant, 4-dimethylaminophenol and/or 4-diethylaminophenol.

[17]

A method for producing a photosensitive resin multilayer body comprising a support film, and a photosensitive resin composition layer formed on the support film, the method comprising:
a step of preparing a coating solution comprising:
   an alkali-soluble polymer,
   a compound having an ethylenically unsaturated double bond,
   a photopolymerization initiator, and
   a peroxide containing acetone peroxide and/or methyl ethyl ketone peroxide, and
   a step of applying the coating solution on the support film and drying the coating solution to form the photosensitive resin composition layer, wherein
   the content of the peroxide in the photosensitive resin composition layer thus formed is 0.01 ppm or more and 1,000 ppm or less, based on the photosensitive resin composition layer.
      [18]

The method for producing a photosensitive resin multilayer body according to item 17, wherein the content of the peroxide in the photosensitive resin composition layer is 0.01 ppm or more and less than 100 ppm based on the photosensitive resin composition layer.

[19]

A photosensitive resin multilayer body comprising a support film, and a photosensitive resin composition layer formed on the support film, wherein the photosensitive resin composition layer comprises:
an alkali-soluble polymer,
a compound having an ethylenically unsaturated double bond,
a photopolymerization initiator,
a colorant,
an oxide and/or a decomposition product of the colorant, and
a radical polymerization inhibitor.
   [20]

The photosensitive resin multilayer body according to item 19, comprising, as the oxide and/or the decomposition product of the colorant, 4-dimethylaminophenol and/or 4-diethylaminophenol.

### Advantageous Effects of Invention

According to the present disclosure, there is provided a multilayer body comprising, on a support film, a photosensitive resin composition layer capable of achieving all of solubility in a developing solution, i.e., developability, adhesion to a substrate, particularly a copper substrate, and colorability of the support film, thus making it possible to improve the resolution of a printed wiring board formed using a dry film resist.

### DESCRIPTION OF EMBODIMENTS

As used herein, the term “(meth)acrylic” means acrylic or methacrylic. The term “(meth)acryloyl” means acryloyl or methacryloyl. The term “(meth)acrylate” means “acrylate” or “methacrylate”.

### Photosensitive Resin Multilayer Body

The photosensitive resin multilayer body of the present disclosure comprises a support film and a photosensitive resin composition layer formed on the support film. If necessary, the photosensitive resin multilayer body may have a protective layer on the surface opposite the support film side of the photosensitive resin composition layer.

### Photosensitive Resin Composition Layer

The photosensitive resin composition layer includes (A) an alkali-soluble polymer, (B) an ethylenically unsaturated bond-containing compound, (C) a photopolymerization initiator, and (D) acetone peroxide and/or methyl ethyl ketone peroxide. If desired, the photosensitive resin composition layer may further include other components such as (E) metal atoms, (F) a sensitizer, (G) a colorant, (H) a radical polymerization inhibitor, and (I) an additive. Each component will be described below.

### (A) Alkali-Soluble Polymer

Alkali-soluble polymer is a polymer that can be dissolved in alkali substances. The alkali-soluble polymer (A) may be single type of a copolymer, a mixture of plural types of copolymers and/or a mixture of plural types of homopolymers.

In relation to the alkali solubility, the acid equivalent of (A) the alkali-soluble polymer is preferably 100 or more from the viewpoint of development resistance of the photosensitive resin composition layer, and development resistance, resolution and adhesion of the resist pattern. From the viewpoint of developability and removability of the photosensitive resin composition layer, the acid equivalent is preferably 900 or less. The acid equivalent of the alkali-soluble polymer (A) is more preferably 200 to 600, and still more preferably 250 to 500. The acid equivalent refers to the weight (unit: gram) of a linear polymer having 1 equivalent of carboxyl groups therein. When the component (A) contains multiple types of copolymers, the acid equivalent means the acid equivalent of the whole mixture.

The alkali-soluble polymer (A) is more preferably a polymer having functional groups contributing to the alkali solubility in an amount sufficient to dissolve in a desired alkali substance. Examples of the functional groups contributing to the alkali solubility include a carboxyl group. The carboxyl group is preferable because of enhancing the developability and removability of the photosensitive resin composition layer with respect to an aqueous alkali solution. The amount sufficient to dissolve in the alkali substance is typically 100 to 600, preferably 250 to 450, in terms of the acid equivalent. The acid equivalent is preferably adjusted to 100 or more from the viewpoint of improving the development resistance, resolution and adhesion, and the acid equivalent is preferably adjusted to 250 or more. Meanwhile, the acid equivalent is preferably adjusted to 600 or less from the viewpoint of improving the developability and removability, and the acid equivalent is preferably controlled to 450 or less.

The weight-average molecular weight of the alkali-soluble polymer (A) is preferably 5,000 to 500,000. It is preferable that the weight-average molecular weight is 500,000 or less from the viewpoint of improving the resolution and developability. The weight-average molecular weight is preferably 300,000 or less, and more preferably 200,000 or less. Meanwhile, it is preferable that the weight-average molecular weight is 5,000 or more from the viewpoint of controlling the properties of the development agglomerate, and the properties of the unexposed film, such as edge fusing property and cut chipping property in the photosensitive resin multilayer body. The weight-average molecular weight is preferably 10,000 or more, and more preferably 20,000 or more. The edge fusing property is the phenomenon in which the photosensitive resin composition layer protrudes from the end face of a roll when the photosensitive resin multilayer body is wound into a roll shape. The cut chipping property is the phenomenon in which chips fly when the unexposed film is cut with a cutter. When the scattered chips adhere to the upper surface of the photosensitive resin multilayer body, the chips are transferred to the mask in the subsequent exposure step, thus causing defects leading to problems.

The degree of dispersion (sometimes referred to as molecular weight distribution) of the alkali-soluble polymer (A) may be about 1 to 6, and preferably 1 to 4. The degree of dispersion is represented by the ratio of the weight-average molecular weight to the number-average molecular weight, and (degree of dispersion)=(weight-average molecular weight)/(number-average molecular weight). The weight-average molecular weight and number-average molecular weight are values as measured in terms of polystyrene using gel permeation chromatography.

The alkali-soluble polymer (A) is preferably a copolymer, and more preferably a copolymer including an aromatic component as a monomer unit. The alkali-soluble polymer (A) is also preferably a copolymer including at least one first monomer mentioned below and at least one second monomer mentioned below as monomer units.

The first monomer is a carboxylic acid or acid anhydride having one polymerizable unsaturated group in the molecule. Examples of the first monomer include (meth)acrylic acid, fumaric acid, cinnamic acid, crotonic acid, itaconic acid, maleic anhydride, maleic acid half ester and the like. In particular, (meth)acrylic acid is preferable.

The second monomer is a non-acidic molecule, and has at least one polymerizable unsaturated group in the molecule. Examples of the second monomer include methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, 2-hydroxyethyl (meth)acrylate, 2-hydroxypropyl (meth)acrylate, 2-ethylhexyl (meth)acrylate, benzyl (meth)acrylate, and esters of vinyl alcohol. Examples of esters of vinyl alcohol include vinyl acetate, (meth)acrylonitrile, styrene and styrene derivatives. Of these, methyl (meth)acrylate, n-butyl (meth)acrylate, styrene, 2-ethylhexyl (meth)acrylate and benzyl (meth)acrylate are preferable. From the viewpoint of improving the resolution and adhesion of the resist pattern, aromatic components are preferable, and styrene and benzyl (meth)acrylate are more preferable.

Regarding the copolymerization ratio of the first monomer to the second monomer, the copolymerization ratio of the first monomer is preferably 10 to 60 wt % and that of the second monomer is preferably 40 to 90 wt %, from the viewpoint of adjusting the alkali solubility of the alkali-soluble polymer (A). The copolymerization ratio of the first monomer is more preferably 15 to 35 wt % and that of the second monomer is more preferably 65 to 85 wt %.

The alkali-soluble polymer (A) is preferably synthesized by adding an appropriate amount of a radical polymerization initiator such as benzoyl peroxide or azobis(isobutyronitrile) to a solution prepared by diluting a mixture of the first monomer and the second monomer with a solvent such as acetone, methyl ethyl ketone (MEK) or isopropanol, followed by heating and stirring. The synthesis may be sometimes carried out while adding dropwise a part of the mixture to the reaction solution. After completion of the reaction, a solvent may be further added to adjust to the desired concentration. As a means of synthesis, bulk polymerization, suspension polymerization or emulsion polymerization may be used in addition to solution polymerization.

The ratio of the alkali-soluble polymer (A) (the total when using a mixture of plural types of alkali-soluble polymers) to the total amount of the photosensitive resin composition layer is preferably 10 to 90 wt %, more preferably 30 to 70 wt %, and still more preferably 40 to 60 wt %. The ratio of the component (A) to the total amount of the photosensitive resin composition layer is preferably 90 wt % or less from the viewpoint of controlling the developing time. Meanwhile, the ratio of the component (A) to the total amount of the photosensitive resin composition layer is preferably 10 wt % or more from the viewpoint of improving the edge fusing property.

The photosensitive resin composition layer preferably contains, as the component (A), one or more components selected from the group consisting of the following (a-1) and (a-2):
(a-1) an acrylic copolymer derived from a copolymerization component containing 15 to 60 wt % of styrene and one or more acrylic monomers selected from the group consisting of acrylic acid, methacrylic acid, acrylic acid ester and methacrylic acid ester; and
(a-2) an acrylic copolymer derived from a copolymerization component containing 20 to 85 wt % of benzyl methacrylate and one or more acrylic monomers selected from the group consisting of acrylic acid, methacrylic acid, acrylic acid ester, and methacrylic acid ester other than benzyl methacrylate, from the viewpoint of high resolution. The ratio of the total amount of the component (a-1) and the component (a-2) to the total amount of the photosensitive resin composition layer is preferably 10 to 60 wt % from the viewpoint of high resolution. From the viewpoint of resolution, the ratio is preferably 20 wt % or more, more preferably 30 wt % or more, and from the viewpoint of cut chipping property, the ratio is preferably 55 wt % or less, and more preferably 50 wt % or less.

The polymerization component in (a-1) may consist of only styrene and the acrylic monomer, or may further contain other monomers. The polymerization component in (a-2) may consist of benzyl methacrylate and the acrylic monomer, or may further contain other monomers. Particularly preferred examples of a combination of 15 to 60 wt % of styrene and 20 to 35 wt % of methacrylic acid, the balance being methyl methacrylate, a combination of 30 to 50 wt % of styrene, 20 to 40 wt % of methacrylic acid and 10 to 20 wt % of 2-ethylhexyl acrylate, the balance being 2-hydroxyethyl methacrylate, or a combination of 20 to 60 wt % of benzyl methacrylate and 10 to 30 wt % of styrene, the balance being methacrylic acid, a combination of 60 to 85 wt % of benzyl methacrylate and 0 to 15 wt % of 2-ethylhexyl acrylate, the balance being methacrylic acid, and the like. It is preferable to contain a monomer having an aralkyl group and/or styrene as monomers is from the viewpoint of chemical resistance, adhesion, high resolution, or foot shape of the resist pattern.

(B) Compound having Ethylenically Unsaturated Double Bond

The compound having an ethylenically unsaturated double bond (B) is a compound having the polymerizability due to having an ethylenically unsaturated group in a structure thereof. From the viewpoint of addition polymerizability, the ethylenically unsaturated bond is preferably a terminal ethylenically unsaturated group.

The compound having an ethylenically unsaturated double bond (B) preferably contains a compound having a (meth)acryloyl group in the molecule from the viewpoint of curability and compatibility with the alkali-soluble polymer (A). Examples of the compound having a (meth)acryloyl group in the molecule include a compound obtained by adding (meth)acrylic acid to one end of a polyalkylene oxide, or those obtained by adding (meth)acrylic acid to one end of a polyalkylene oxide, followed by alkyl etherification or allyl etherification of the other end.

Examples of such compound include phenoxyhexaethylene glycol mono (meth)acrylate, which is (meth)acrylate of a compound obtained by adding polyethylene glycol to a phenyl group; 4-normalnonylphenoxyheptaethylene glycol dipropylene glycol (meth)acrylate, which is a (meth)acrylate of a compound obtained by adding polypropylene glycol to which 2 mols on average of propylene oxide (hereinafter sometimes abbreviated as PO) are added and polyethylene glycol to which 7 mols on average of ethylene oxide (hereinafter sometimes abbreviated as EO) are added, to nonylphenol; 4-normalnonylphenoxypentaethylene glycol monopropylene glycol (meth)acrylate, which is a (meth)acrylate of a compound obtained by adding polypropylene glycol to which 1 mol on average of PO is added and polyethylene glycol to which 5 mols on average of EO are added, to nonylphenol; and 4-normalnonylphenoxyoctaethylene glycol (meth)acrylate (e.g., M-114 manufactured by TOAGOSEI CO., LTD.), which is an acrylate of a compound obtained by adding polyethylene glycol to which 8 mols on average of EO are added, to nonylphenol.

Examples of the compound having an ethylenically unsaturated double bond (B) also include a compound having a (meth)acryloyl group at both ends of an alkylene oxide chain, or a compound having a (meth)acryloyl group at both chain ends of an alkylene oxide in which an EO chain and a PO chain are bonded in random or blocking manner.

Examples of such compound include tetraethylene glycol di(meth)acrylate, pentaethylene glycol di(meth)acrylate, hexaethylene glycol di(meth)acrylate, heptaethylene glycol di(meth)acrylate, octaethylene glycol di(meth)acrylate, nonaethylene glycol di(meth)acrylate, decaethylene glycol di(meth)acrylate, polyethylene glycol (meth)acrylate such as a compound having a (meth)acryloyl group at both ends of 12 mols of EO chain, polypropylene glycol di(meth)acrylate, polybutylene glycol di(meth)acrylate and the like. Examples of the polyalkylene oxide di(meth)acrylate compound having an EO group and a PO group in the compound include a dimethacrylate of glycol in which 3 mols on average of EO are respectively added to both ends of polypropylene glycol to which 12 mols on average of PO are added, a dimethacrylate of glycol in which 15 mols on average of EO are respectively added to both ends of polypropylene glycol to which 18 mols on average of PO are added, and the like. Furthermore, preferred are polyethylene glycol di(meth)acrylate, polypropylene glycol di(meth)acrylate, and di(meth)acrylate having both ethylene oxide and polypropylene oxide (e.g., “FA-023M, FA-024M, FA-027M, product name, manufactured by Hitachi Kasei Kogyo Kabushiki Kaisha) from the viewpoint of flexibility, resolution, adhesion and the like.

From the viewpoint of resolution and adhesion, a compound having an ethylenically unsaturated double bond (B) is preferably a compound having a (meth)acryloyl group at both ends of bisphenol A underwent alkylene oxide modification. Examples of the alkylene oxide modification include EO modification, PO modification, butylene oxide modification, pentylene oxide modification, hexylene oxide modification and the like. From the viewpoint of resolution and adhesion, a compound having a (meth)acryloyl group at both ends of bisphenol A underwent EO modification is particularly preferable.

Examples of such compound include 2,2-bis(4-((meth)acryloxypolyethoxy)phenyl)propanes such as 2,2-bis(4-((meth)acryloxydiethoxy)phenyl)propane (e.g., NK ester BPE-200 manufactured by SHIN-NAKAMURA CHEMICAL CO., LTD.), 2,2-bis(4-((meth)acryloxytriethoxy)phenyl)propane, 2,2-bis(4-((meth)acryloxytetraethoxy)phenyl)propane, 2,2-bis(4-((meth)acryloxypentaethoxy)phenyl)propane (e.g., NK ester BPE-500 manufactured by SHIN-NAKAMURA CHEMICAL CO., LTD.), 2,2-bis(4-((meth)acryloxyhexaethoxy)phenyl)propane, 2,2-bis(4-((meth)acryloxyheptaethoxy)phenyl)propane, 2,2-bis(4-((meth)acryloxyoctaethoxy)phenyl)propane, 2,2-bis(4-((meth)acryloxynonaethoxy)phenyl)propane, 2,2-bis(4-((meth)acryloxydecaethoxy)phenyl)propane, 2,2-bis(4-((meth)acryloxyundecaethoxy)phenyl)propane, 2,2-bis(4-((meth)acryloxydodecaethoxy)phenyl)propane, 2,2-bis(4-((meth)acryloxytridecaethoxy)phenyl)propane, 2,2-bis(4-((meth)acryloxytetradecaethoxy)phenyl)propane, 2,2-bis(4-((meth)acryloxypentadecaethoxy)phenyl)propane, and 2,2-bis(4-((meth)acryloxyhexadecaethoxy)phenyl)propane. Also, preferred are EO-modified and PO-modified compounds, such as a di(meth)acrylate of polyalkylene glycol in which 2 mols on average of PO and 6 mols on average of EO are respectively added to both ends of bisphenol A, or a di(meth)acrylate of polyalkylene glycol in which 2 mols on average of PO and 15 mols on average of EO are respectively added to both ends of bisphenol A, and a di(meth)acrylate of polyethylene glycol in which 5 mols on average of EO are respectively added to both ends of bisphenol A, BPE-500 (e.g., BPE-200 manufactured by SHIN-NAKAMURA CHEMICAL CO., LTD.) from the viewpoint of resolution and adhesion. In these compounds having a (meth)acryloyl groups at both ends of bisphenol A underwent alkylene oxide modification, the number of mols of EO per 1 mol of bisphenol A is preferably 10 mol or more and 30 mol or less from the viewpoint of improving the resolution, adhesion and flexibility.

It is preferable to contain, as the compound having an ethylenically unsaturated double bond (B), a compound having more than two (meth)acryloyl groups in one molecule in view of exhibiting high resolution. The number of (meth)acryloyl groups in one molecule is more preferably 3 or more. From the viewpoint of removability, the number of (meth)acryloyl groups in one molecule is preferably 6 or less, and more preferably 4 or less. The number of (meth)acryloyl groups in one molecule is preferably 3 or 4 from the viewpoint of high resolution and removability. A compound having more than two (meth)acryloyl groups in one molecule has 3 mols or more of groups capable of adding an alkylene oxide group into the molecule as a central skeleton (i.e., 3 or more groups per central skeleton) and is obtained by forming a (meth)acrylate from an alcohol to which an alkylene oxide group such as an EO group, a PO group or a butylene oxide group is added, and (meth)acrylic acid. If the central skeleton is alcohol, the compound can also be obtained by directly forming (meth)acrylic acid and (meth)acrylate. Examples of the compound capable of serving as the central skeleton include glycerin, trimethylolpropane, pentaerythritol, dipentaerythritol, isocyanurate ring and the like.

Examples of such compound include EO (3 mols)-modified triacrylate of trimethylolpropane, EO (6 mols)-modified triacrylate of trimethylolpropane, EO (9 mols)-modified triacrylate of trimethylolpropane, EO (12 mols)-modified triacrylate of trimethylolpropane, EO (3 mols)-modified triacrylate of glycerin (e.g., A-GLY-3E manufactured by SHIN-NAKAMURA CHEMICAL CO., LTD.), EO (9 mols)-modified triacrylate of glycerin (e.g., A-GLY-9E manufactured by Shin-Nakamura Chemical Industry Co., Ltd.), EO (6 mols) PO (6 mols)-modified triacrylate of glycerin (A-GLY-0606PE), EO (9 mols) PO (9 mols)-modified triacrylate of glycerin (A-GLY-0909PE), 4EO-modified tetraacrylate of pentaerythritol (e.g., SR-494 manufactured by Sartomer Japan Inc.), 35EO-modified tetraacrylate of pentaerythritol (e.g., NK Ester ATM-35E manufactured by SHIN-NAKAMURA CHEMICAL CO., LTD.), dipentaerythritol tetraacrylate, 7:3 mixture of pentaerythritol triacrylate and pentaerythritol tetraacrylate (e.g., M-306 manufactured by TOAGOSEI CO., LTD.) and the like. Examples of the compound having at least three methacryloyl groups include trimethacrylates such as ethoxylated glycerin trimethacrylate, ethoxylated isocyanurate trimethacrylate, pentaerythritol trimethacrylate, and trimethylolpropane trimethacrylate (e.g., trimethacrylate in which 21 mols on average of ethylene oxide are added to trimethylolpropane and trimethacrylate in which 30 mols on average of ethylene oxide are added to trimethylolpropane are preferable from the viewpoint of flexibility, adhesion, and suppression of bleeding out); tetramethacrylates such as ditrimethylolpropane tetramethacrylate, pentaerythritol tetramethacrylate and dipentaerythritol tetramethacrylate; pentamethacrylates such as dipentaerythritol pentamethacrylate and the like; and hexamethacrylates such as dipentaerythritol pentamethacrylate. Of these, tetra-, penta- or hexamethacrylate is preferable.

Of these, preferred examples of the compound having an ethylenically unsaturated double bond (B) are those which have a melting point lower than room temperature and do not easily solidify during storage, from the viewpoint of handling. In particular, 3EO-modified triacrylate of trimethylolpropane and 4EO-modified tetraacrylate of pentaerythritol are preferable.

The content of the compound having more than two (meth)acryloyl groups in one molecule is preferably 50 to 100 wt % of the compound having an ethylenically unsaturated double bond (B). The content is preferably 50 wt % or more, and more preferably 60 wt % or more, from the viewpoint of resolution. The content may be 100 wt %, and may be preferably 95 wt % or less, and more preferably 90 wt % or less, from the viewpoint of removability.

The component (B) can appropriately contain, in addition to the above compounds, for example, the following compounds. Examples thereof include 1,6-hexanediol di(meth)acrylate, 1,4-cyclohexanediol di(meth)acrylate, 2-di(p-hydroxyphenyl)propane di(meth)acrylate, 2,2-bis[(4-(meth)acryloxypolypropyleneoxy)phenyl]propane, 2,2-bis[(4-(meth)acryloxypolybutyleneoxy)phenyl]propane, glycerol tri(meth)acrylate, trimethylolpropane tri(meth)acrylate, polyoxypropyltrimethylolpropane tri(meth)acrylate, dipentaerythritol penta(meth)acrylate, trimethylolpropane triglycidyl ether tri(meth)acrylate, β-hydroxypropyl-β′-(acryloyloxy)propyl phthalate, nonylphenoxypolypropylene glycol (meth)acrylate, nonylphenoxypolybutylene glycol (meth)acrylate, polypropylene glycol mono(meth)acrylate and the like. It is also possible to exemplify the following urethane compounds, for example, urethane compounds of hexamethylene diisocyanate, tolylene diisocyanate or a diisocyanate compound (e.g., 2,2,4-trimethylhexamethylene diisocyanate) and a compound having a hydroxyl group and a (meth)acrylic group in one molecule, such as 2-hydroxypropyl acrylate or oligopropylene glycol monomethacrylate. Specifically, there is a reaction product of hexamethylene diisocyanate and oligopropylene glycol monomethacrylate (e.g., BLEMMER PP1000 manufactured by NOF Corporation). It is also possible to exemplify di- or tri(meth)acrylates of isocyanuric acid esters modified with polypropylene glycol or polycaprolactone. It is also possible to exemplify a urethane oligomer obtained by reacting the end of a urethane compound obtained as a polyadduct of diisocyanate and polyol with a compound having an ethylenically unsaturated double bond and a hydroxyl group.

It is possible to contain, as the compound having an ethylenically unsaturated bond (B), compounds having one ethylenically unsaturated bond, such as 4-normalnonylphenoxyoctaethylene glycol acrylate, 4-normalnonylphenoxytetraethylene glycol acrylate and γ-chloro-β-hydroxypropyl-β′-methacryloyloxyethyl-o-phthalate. From the viewpoint of removability and cured film flexibility, and from the viewpoint of sensitivity, resolution and adhesion, it is preferable to contain γ-chloro-β-hydroxypropyl-β′-methacryloyloxyethyl-o-phthalate.

The compound having an ethylenically unsaturated double bond (B) preferably has a hydroxyl group in the molecule, thus making it possible to obtain a photosensitive resin multilayer body which is particularly excellent in sensitivity (productivity), resolution and adhesion.

The ratio of the compound having an ethylenically unsaturated double bond (B) to the total amount of the photosensitive resin composition layer is preferably 5 to 70 wt %. This ratio is preferably 5 wt % or more from the viewpoint of sensitivity, resolution and adhesion, more preferably 10 wt % or more, and still more preferably 20 wt % or more. Meanwhile, the ratio is preferably 70 wt % or less from the viewpoint of suppressing edge fusion and delay in removing of the cured resist, and the ratio is more preferably 60 wt % or less, and still more preferably 50 wt % or less.

### (C) Photopolymerization Initiator

The photopolymerization initiator (C) preferably contains a hexaarylbiimidazole compound from the viewpoint of sensitivity and resolution.

Examples of the hexaarylbiimidazole compound include 2-(o-chlorophenyl)-4,5-diphenylbiimidazole, 2,2′,5-tris-(o-chlorophenyl)-4-(3,4-dimethoxyphenyl)-4′,5′-diphenylbiimidazole, 2,4-bis-(o-chlorophenyl)-5-(3,4-dimethoxyphenyl)-diphenylbiimidazole, 2,4,5-tris-(o-chlorophenyl)-diphenylbiimidazole, 2-(o-chlorophenyl)-bis-4,5-(3,4-dimethoxyphenyl)-biimidazole, 2,2′-bis-(2-fluorophenyl)-4,4′,5,5′-tetrakis-(3-methoxyphenyl)-biimidazole, 2,2′-bis-(2,3-difluoromethylphenyl)-4,4′,5,5′-tetrakis-(3-methoxyphenyl)-biimidazole, 2,2′-bis-(2,4-difluorophenyl)-4,4′,5,5′-tetrakis-(3-methoxyphenyl)-biimidazole, 2,2′-bis-(2,5-difluorophenyl)-4,4′,5,5′-tetrakis-(3-methoxyphenyl)-biimidazole, 2,2′-bis-(2,6-difluorophenyl)-4,4′,5,5′-tetrakis-(3-methoxyphenyl)-biimidazole, 2,2′-bis-(2,3,4-trifluorophenyl)-4,4′,5,5′-tetrakis-(3-methoxyphenyl)-biimidazole, 2,2′-bis-(2,3,5-trifluorophenyl)-4,4′,5,5′-tetrakis-(3-methoxyphenyl)-biimidazole, 2,2′-bis-(2,3,6-trifluorophenyl)-4,4′,5,5′-tetrakis-(3-methoxyphenyl)-biimidazole, 2,2′-bis-(2,4,5-trifluorophenyl)-4,4′,5,5′-tetrakis-(3-methoxyphenyl)-biimidazole, 2,2′-bis-(2,4,6-trifluorophenyl)-4,4′,5,5′-tetrakis-(3-methoxyphenyl)-biimidazole, 2,2′-bis-(2,3,4,5-tetrafluorophenyl)-4,4′,5,5′-tetrakis-(3-methoxyphenyl)-biimidazole, 2,2′-bis-(2,3,4,6-tetrafluorophenyl)-4,4′,5,5′-tetrakis-(3-methoxyphenyl)-biimidazole, and 2,2′-bis-(2,3,4,5,6-pentafluorophenyl)-4,4′,5,5′-tetrakis-(3-methoxyphenyl)-biimidazole. Of these, from the viewpoint of sensitivity and resolution, a 2-(o-chlorophenyl)-4,5-diphenylimidazole dimer is preferable.

Examples of the component (C) include, in addition to the hexaarylbiimidazole compound, N-aryl-α-amino acid compounds, quinones, aromatic ketones, acetophenones, acylphosphine oxides, benzoin or benzoin ethers, dialkyl ketals, thioxanthones, dialkylaminobenzoic acid esters, oxime esters, acridines, ester compounds of N-arylamino acids, halogen compounds and the like.

Examples of the N-aryl-α-amino acid compound include N-phenylglycine, N-methyl-N-phenylglycine, N-ethyl-N-phenylglycine and the like. In particular, N-phenylglycine is preferable because of having a high sensitizing effect.

Examples of quinones include 2-ethylanthraquinone, octaethylanthraquinone, 1,2-benzanthraquinone, 2,3-benzanthraquinone, 2-phenylanthraquinone, 2,3-diphenylanthraquinone, 1-chloroanthraquinone, 2-chloroanthraquinone, 2-methylanthraquinone, 1,4-naphthoquinone, 9,10-phenanthraquinone, 2-methyl-1,4-naphthoquinone, 9,10-phenanthraquinone, 2-methyl-1,4-naphthoquinone, 2,3-dimethylanthraquinone, 3-chloro-2-methylanthraquinone and the like.

Examples of aromatic ketones include benzophenone, Michler's ketone [4,4′-bis(dimethylamino)benzophenone], 4,4′-bis(diethylamino)benzophenone and 4-methoxy-4′-dimethylaminobenzophenone.

Examples of acetophenones include 2-hydroxy-2-methyl-1-phenylpropan-1-one, 1-(4-isopropylphenyl)-2-hydroxy-2-methylpropan-1-one, 1-(4-dodecylphenyl)-2-hydroxy-2-methylpropan-1-one, 4-(2-hydroxyethoxy)-phenyl(2-hydroxy-2-propyl) ketone, 1-hydroxycyclohexyl phenyl ketone, 2-benzyl-2-dimethylamino-1-(4-morpholinophenyl)-butanone-1, and 2-methyl-1-[4-(methylthio)phenyl]-2 morpholino-propanone-1. Examples of commercially available products include Irgacure 907, Irgacure 369 and Irgacure 379 manufactured by Ciba Specialty Chemicals.

Examples of acylphosphine oxides include 2,4,6-trimethylbenzyldiphenylphosphine oxide, bis(2,4,6-trimethylbenzoyl)-phosphine oxide, bis(2,6-dimethoxybenzoyl)-2,4,4-trimethyl-pentylphosphine oxide and the like. Examples of commercially available products include Lucirin TPO manufactured by BASF Corporation and Irgacure 819 manufactured by Ciba Specialty Chemicals.

Examples of benzoin or benzoin ethers include benzoin, benzoin ethyl ether, benzoin phenyl ether, methylbenzoin and ethylbenzoin.

Examples of dialkyl ketals include benzyl dimethyl ketal and benzyl diethyl ketal.

Examples of thioxanthones include 2,4-diethylthioxanthone, 2,4-diisopropylthioxanthone and 2-chlorothioxanthone.

Examples of dialkylaminobenzoic acid esters include ethyl dimethylaminobenzoate, ethyl diethylaminobenzoate, ethyl-p-dimethylaminobenzoate and 2-ethylhexyl-4-(dimethylamino)benzoate.

Examples of oxime esters include 1-phenyl-1,2-propanedione-2-O-benzoyloxime and 1-phenyl-1,2-propanedione-2-(O-ethoxycarbonyl)oxime. Examples of commercially available products include CGI-325, Irgacure OXE01 and Irgacure OXE02 manufactured by Ciba Specialty Chemicals.

Examples of acridines include 1,7-bis(9,9′-acridinyl)heptane, 9-phenylacridine, 9-methylacridine, 9-ethylacridine, 9-chloroethylacridine, 9-methoxyacridine, 9-ethoxyacridine, 9-(4-methylphenyl)acridine, 9-(4-ethylphenyl)acridine, 9-(4-n-propylphenyl)acridine, 9-(4-n-butylphenyl)acridine, 9-(4-tert-butylphenyl)acridine, 9-(4-methoxyphenyl)acridine, 9-(4-ethoxyphenyl)acridine, 9-(4-acetylphenyl)acridine, 9-(4-dimethylaminophenyl)acridine, 9-(4-chlorophenyl)acridine, 9-(4-bromophenyl)acridine, 9-(3-methylphenyl)acridine, 9-(3-tert-butylphenyl)acridine, 9-(3-acetylphenyl)acridine, 9-(3-dimethylaminophenyl)acridine, 9-(3-diethylaminophenyl)acridine, 9-(3-chlorophenyl)acridine, 9-(3-bromophenyl)acridine, 9-(2-pyridyl)acridine, 9-(3-pyridyl)acridine and 9-(4-pyridyl)acridine.

Examples of ester compounds of N-arylamino acids include methyl esters of N-phenylglycine, ethyl esters of N-phenylglycine, n-propyl esters of N-phenylglycine, isopropyl esters of N-phenylglycine, 1-butyl esters of N-phenylglycine, 2-butyl esters of N-phenylglycine, tert-butyl esters of N-phenylglycine, pentyl esters of N-phenylglycine, hexyl esters of N-phenylglycine, pentyl esters of N-phenylglycine, octyl esters of N-phenylglycine and the like.

Examples of halogen compounds include amyl bromide, isoamyl bromide, isobutylene bromide, ethylene bromide, diphenylmethyl bromide, benzyl bromide, methylene bromide, tribromomethylphenylsulfone, carbon tetrabromide, tris(2,3-dibromopropyl)phosphate, trichloroacetamide, amyl iodide, isobutyl iodide, 1,1,1-trichloro-2,2-bis(p-chlorophenyl)ethane, chlorinated triazine compounds, diallyliodonium compounds and the like. In particular, tribromomethylphenylsulfone is preferable. From the viewpoint of sensitivity, the content of the halogen compound in the photosensitive resin composition layer is preferably 0.01 to 3 wt % based on the total amount of components (A) to (J).

These photopolymerization initiators may be used alone or in combination of two or more thereof.

The ratio of the photopolymerization initiator (C) to the total amount of the photosensitive resin composition layer is preferably 0.1 to 20 wt %. This ratio is preferably set at 0.1 wt % or more from the viewpoint of obtaining sufficient sensitivity, more preferably 0.2 wt % or more, and still more preferably 0.5 wt % or more. Meanwhile, this ratio is preferably set at 20 wt % or less from the viewpoint of obtaining high resolution and suppressing agglomeration in the developing solution, and more preferably 10 wt % or less.

### (D) Peroxide

The photosensitive resin composition layer includes peroxide containing acetone peroxide and/or methyl ethyl ketone peroxide. The content of the peroxide is 0.01 ppm or more and 1,000 ppm or less, based on the total mass of the photosensitive resin composition layer. When the content of the peroxide is within this range, it is possible to achieve all of the color developability upon exposure, solubility in a developing solution (i.e., developability) and colorability of the support film. Although the reason is not limited to theory, when the content of the peroxide exceeds 1,000 ppm, the stability of the film during lamination heating deteriorates, and an unintended polymerization reaction of the double bond functional group occurs, leading to delay in developing time due to deterioration of the solubility in the developing solution, and deterioration of the colorability of the support film. This is probably because when the content of the peroxide is less than 0.01 ppm, the number of radicals initiated during exposure decreases, resulting in deterioration of color developability upon exposure and patterning visibility. There is an advantage that good color developability upon exposure reduces errors such as accidental double exposure of already exposed areas in the exposure process, and good developability enables less residue remaining in the resist pattern. There is also an advantage that good colorability of the support film makes it easy to visually detect the position of the film laminated on the substrate, and also enables reduction in errors in a series of patterning processes.

The lower limit of the content of the peroxide is preferably 0.1 ppm or more, 0.5 ppm or more, 1 ppm or more, 5 ppm or more, or 10 ppm or more, based on the total weight of the photosensitive resin composition layer. The upper limit of the content of the peroxide that can be combined with these lower limits is preferably 500 ppm or less or 200 ppm or less, based on the total weight of the photosensitive resin composition layer, and may be 100 ppm or less, less than 100 ppm, 50 ppm or less, 10 ppm or less, 5 ppm or less, or 1 ppm or less. The content of the peroxide is preferably within a range of 0.01 ppm or more and 500 ppm or less, 0.01 ppm or more and 200 ppm or less, 0.01 ppm or more and 100 ppm or less, or 0.01 ppm or more and less than 100 ppm, 0.1 ppm or more and 500 ppm or less, 0.1 ppm or more and 200 ppm or less, 0.1 ppm or more and 100 ppm or less, or 0.1 ppm or more and less than 100 ppm, 0.5 ppm or more and 500 ppm or less, 0.5 ppm or more and 200 ppm or less, 0.5 ppm or more and 100 ppm or less, or 0.5 ppm or more and less than 100 ppm, 1 ppm or more and 500 ppm or less, 1 ppm or more and 200 ppm or less, 1 ppm or more and 100 ppm or less, 1 ppm or more and less than 100 ppm, 5 ppm or more and 500 ppm or less, 5 ppm or more and 200 ppm or less, 5 ppm or more and 100 ppm or less, or 5 ppm or more and less than 100 ppm, based on the total weight of the photosensitive resin composition layer. When the content of the peroxide is within the above range, it is possible to achieve and improve all of the color developability upon exposure, solubility (i.e., developability) in a developing solution, and colorability of the support film.

The content (total amount) of the peroxide in the photosensitive resin composition layer can be measured by gas chromatography (GC) when the structure of the peroxide can be identified. When the structure of the peroxide cannot be identified, free iodine produced by the reaction between the peroxide and potassium iodide is subjected to potentiometric titration with a sodium thiosulfate solution, and then the decomposition product derived from the peroxide structure produced after titration is specified. It is possible to calculate the total amount of the peroxide included in the photosensitive resin composition layer from the value of the potentiometric titration and the structure of the specified peroxide.

### (E) Metal Atom

The photosensitive resin composition layer may optionally contain metal atoms. The content of metal atoms is preferably 0.005 ppm or more and 70 ppm or less, and more preferably 0.01 ppm or more and 5 ppm or less, based on the total amount of the photosensitive resin composition layer. When the amount of metal atoms is within this range, it is possible to achieve both solubility in a developing solution, i.e. developability, and adhesion to a substrate, particularly a copper substrate. Good developability results in less residue remaining in the resist pattern, and good adhesion to the substrate makes it possible to form a finer resist pattern.

Examples of metal atoms include iron atoms, calcium atoms, aluminum atoms and sodium atoms.

When the photosensitive resin composition contain iron atoms, the content of iron atoms is preferably 0.01 ppm or more and 10 ppm or less, based on the total amount of the photosensitive resin composition layer.

The lower limit of the content of iron atoms in the photosensitive resin composition layer is preferably 0.01 ppm or more, based on the photosensitive resin composition layer. When the content of iron atoms is the lower limit or more, the interaction with the metal surface of the substrate increases, resulting in excellent adhesion. The reason for this is considered that, for example, stably existing iron ions are trivalent, so that iron ions can be coordinately bonded between CuO⁻ on the substrate surface and carboxylic acid of the binder (e.g., CuO⁻ . . . Fe³⁺ . . . COO⁻).

The content of iron atoms in the photosensitive resin composition layer may be preferably 0.03 ppm or more, 0.05 ppm or more, 0.1 ppm or more, 0.2 ppm or more, 0.3 ppm or more, 0.4 ppm or more, 0.5 ppm or more, 0.6 ppm or more, 0.7 ppm or more, 0.8 ppm or more, 0.9 ppm or more, 1.0 ppm or more, 1.1 ppm or more, 1.2 ppm or more, 1.3 ppm or more, 1.4 ppm or more, 1.5 ppm or more, 2.0 ppm or more, 3.0 ppm or more, 4.0 ppm or more, or 5.0 ppm or more. The higher the content of iron atoms, the more the adhesion is improved.

The upper limit of the content of iron atoms in the photosensitive resin composition layer which can be combined with the above lower limit is preferably 10 ppm or less, based on the total amount of the photosensitive resin composition layer. When the content of iron atoms is the upper limit or less, the solubility in a developing solution is moderate, and the developing time tends to be moderate.

The upper limit of the content of iron atoms in the photosensitive resin composition layer which can be combined with the lower limit may be preferably 5.0 ppm or less, 4.0 ppm or less, 3.0 ppm or less, 2.0 ppm or less, 1.5 ppm or less, 1.4 ppm or less, 1.3 ppm or less, 1.2 ppm or less, 1.1 ppm or less, 1.0 ppm or less, 0.9 ppm or less, 0.8 ppm or less, 0.7 ppm or less, 0.6 ppm or less, 0.5 ppm or less, 0.4 ppm or less, 0.3 ppm or less, 0.2 ppm or less, or 0.1 ppm or less. The less the content of ion atoms, the more the developing time can be reduced.

The content of iron atoms in the photosensitive resin composition layer is more preferably 0.05 ppm or more and 2.0 ppm or less, based on the photosensitive resin composition layer. By setting the content of iron atoms within the above range, the solubility in a developing solution, i.e., developability, and adhesion to a substrate, particularly a copper substrate, can be further improved. Good developability has the effect of enabling less residue remaining in the resist pattern, and good adhesion to the substrate has the effect of being capable of forming a finer resist pattern.

Examples of means for adjusting the content of iron atoms in the photosensitive resin composition layer to within the range of 0.01 ppm or more and 10 ppm or less include, but are not particularly limited, to various adjustments of the composition of the photosensitive resin composition with respect to each component.

When the photosensitive resin composition layer contains calcium atoms, the content of calcium atoms is 0.005 ppm or more and 5 ppm or less, based on the total amount of the photosensitive resin composition layer.

The lower limit of the content of calcium atoms in the photosensitive resin composition layer is preferably 0.005 ppm or more, based on the total amount of the photosensitive resin composition layer. When the content of calcium atoms is the lower limit or more, the interaction with the metal surface of the substrate increases, and the adhesion tends to be excellent. The reason for this is considered that, for example, stably existing calcium ions are divalent, so that calcium ions can be coordinately bonded between CuO⁻ on the substrate surface and carboxylic acid of the binder (e.g., CuO⁻ . . . Ca²⁺ . . . COO⁻).

The lower limit of the content of calcium atoms in the photosensitive resin composition layer may be preferably 0.01 ppm or more, 0.03 ppm or more, 0.05 ppm or more, 0.08 ppm or more, 0.1 ppm or more, 0.2 ppm or more, 0.3 ppm or more, 0.4 ppm or more, 0.5 ppm or more, 0.6 ppm or more, 0.7 ppm or more, 0.8 ppm or more, 0.9 ppm or more, 1.0 ppm or more, 1.1 ppm or more, 1.2 ppm or more, 1.3 ppm or more, 1.4 ppm or more, 1.5 ppm or more, 2.0 ppm or more, 3.0 ppm or more, or 4.0 ppm or more. The higher the content of calcium atoms, the more the adhesion is improved.

The upper limit of the content of calcium atoms in the photosensitive resin composition layer which can be combined with the lower limit is preferably 5 ppm or less, based on the total amount of the photosensitive resin composition layer. When the content of calcium atoms is the upper limit or less, the solubility in a developing solution is moderate, and the developing time tends to be moderate.

The upper limit of the content of calcium atoms in the photosensitive resin composition layer which can be combined with the lower limit may be preferably 4.0 ppm or less, 3.0 ppm or less, 2.0 ppm or less, 1.5 ppm or less, 1.4 ppm or less, 1.3 ppm or less, 1.2 ppm or less, 1.1 ppm or less, 1.0 ppm or less, 0.9 ppm or less, 0.8 ppm or less, 0.7 ppm or less, 0.6 ppm or less, 0.5 ppm or less, 0.4 ppm or less, 0.3 ppm or less, 0.2 ppm or less, 0.1 ppm or less, or 0.05 ppm or less. The less the content of calcium atoms, the more the developing time can be reduced.

The content of calcium atoms in the photosensitive resin composition layer is more preferably 0.005 ppm or more and 5 ppm or less, and still more preferably 0.03 ppm or more and 1.0 ppm or less, based on the total amount of the photosensitive resin composition layer. When the content of calcium atoms is within the above range, it is possible to achieve both solubility in a developing solution, i.e., developability, and adhesion to a substrate, particularly a copper substrate. Good developability has the effect of enabling less residue remaining in the resist pattern, and good adhesion to the substrate has the effect of being capable of forming a finer resist pattern.

Examples of means for adjusting the content of calcium atoms in the photosensitive resin composition layer to within the range of 0.005 ppm or more and 5 ppm or less include, but are not particularly limited, to various adjustments of the composition of the photosensitive resin composition with respect to each component.

When the photosensitive resin composition layer contains aluminum atoms, the content of aluminum atoms is 0.005 ppm or more and 5 ppm or less, based on the total amount of the photosensitive resin composition layer.

The lower limit of the content of aluminum atoms in the photosensitive resin composition layer is preferably 0.005 ppm or more, based on the total amount of the photosensitive resin composition layer. When the content of aluminum atoms is the lower limit or more, the interaction with the metal surface of the substrate increases, and the adhesion tends to be excellent. This is because, for example, stably existing aluminum ions are trivalent, so that aluminum ions can be coordinately bonded between CuO⁻ on the substrate surface and carboxylic acid of the binder (e.g., CuO⁻ . . . Al³⁺ . . . COO⁻).

The lower limit of the content of aluminum atoms in the photosensitive resin composition layer may be preferably 0.01 ppm or more, 0.03 ppm or more, 0.05 ppm or more, 0.08 ppm or more, 0.1 ppm or more, 0.2 ppm or more, 0.3 ppm or more, 0.4 ppm or more, 0.5 ppm or more, 0.6 ppm or more, 0.7 ppm or more, 0.8 ppm or more, 0.9 ppm or more, 1.0 ppm or more, 1.1 ppm or more, 1.2 ppm or more, 1.3 ppm or more, 1.4 ppm or more, 1.5 ppm or more, 2.0 ppm or more, 3.0 ppm or more, or 4.0 ppm or more. The higher the content of aluminum atoms, the more the adhesion is improved.

The upper limit of the content of aluminum atoms in the photosensitive resin composition layer which can be combined with the lower limit is preferably 5 ppm or less, based on the total amount of the photosensitive resin composition layer. When the content of aluminum atoms is the upper limit or less, the solubility in the developing solution is moderate, and the developing time tends to be moderate.

The upper limit of the aluminum atom content in the photosensitive resin composition layer which can be combined with the lower limit may be preferably 4.0 ppm or less, 3.0 ppm or less, 2.0 ppm or less, 1.5 ppm or less, 1.4 ppm or less, 1.3 ppm or less, 1.2 ppm or less, 1.1 ppm or less, 1.0 ppm or less, 0.9 ppm or less, 0.8 ppm or less, 0.7 ppm or less, 0.6 ppm or less, 0.5 ppm or less, 0.4 ppm or less, 0.3 ppm or less, 0.2 ppm or less, 0.1 ppm or less, or 0.05 ppm or less.

The content of aluminum atoms in the photosensitive resin composition layer is more preferably 0.005 ppm or more and 5 ppm or less, still more preferably 0.02 ppm or more and 2.5 ppm or less, and yet more preferably 0.03 ppm or more and 1.0 ppm or less, based on the total amount of the photosensitive resin composition layer. When the content of aluminum atoms is within the above range, it is possible to achieve both solubility in a developing solution, i.e., developability, and adhesion to a substrate, particularly a copper substrate. Good developability has the effect of enabling less residue remaining in the resist pattern, and good adhesion to the substrate has the effect of being capable of forming a finer resist pattern.

Examples of means for adjusting the content of aluminum atoms in the photosensitive resin composition layer to within the range of 0.005 ppm or more and 5 ppm or less include, but are not particularly limited, to various adjustments of the composition of the photosensitive resin composition with respect to each component.

The total content of iron atoms, calcium atoms and aluminum atoms in the photosensitive resin composition layer is preferably 0.02 ppm or more 20 ppm or less. The lower limit of the total content of iron atoms, calcium atoms and aluminum atoms may be preferably 0.03 ppm or more, 0.04 ppm or more, 0.05 ppm or more, 0.06 ppm or more, 0.07 ppm or more, 0.08 ppm or more, 0.09 ppm or more, 0.1 ppm or more, 0.1 ppm or more, 0.11 ppm or more, 0.12 ppm or more, 0.13 ppm or more, 0.14 ppm or more, 0.15 ppm or more, 0.16 ppm or more, 0.17 ppm or more, 0.18 ppm or more, 0.19 ppm or more, 0.2 ppm or more, 0.3 ppm or more, 0.4 ppm or more, 0.5 ppm or more, 0.6 ppm or more, 0.7 ppm or more, 0.8 ppm or more, 0.9 ppm or more, 1.0 ppm or more, 1.5 ppm or more, 2.0 ppm or more, 2.5 ppm or more, 3.0 ppm or more, 3.5 ppm or more, or 4.0 ppm or more.

The upper limit of the total content of iron atoms, calcium atoms and aluminum atoms, which can be combined with the above lower limit may be preferably 15 ppm or less, 10 ppm or less, 5 ppm or less, 4 ppm or less, 3 ppm or less, 2 ppm or less, or 1 ppm or less. The upper limit is preferably 0.11 ppm or more and 5 ppm or less.

When the photosensitive resin composition layer contains sodium atoms, the content of sodium atoms is 1 ppm or more and 50 ppm or less, based on the total amount of the photosensitive resin composition layer.

The lower limit of the content of sodium atoms in the photosensitive resin composition layer is 1 ppm or more, based on the total amount of the photosensitive resin composition layer. Since the photosensitive resin composition body includes a trace amount of sodium ions, it has excellent permeability of the developing solution and water washing water, so that it is possible to perform development without leaving residue even between dense wirings.

The lower limit of the content of sodium atoms in the photosensitive resin composition layer may be 1 ppm or more, 1.5 ppm or more, 2 ppm or more, 3 ppm or more, 4 ppm or more, 5 ppm or more, 6 ppm or more, 7 ppm or more, 8 ppm or more, 9 ppm or more, 10 ppm or more, 15 ppm or more, 16 ppm or more, 17 ppm or more, 18 ppm or more, 19 ppm or more, 20 ppm or more, 30 ppm or more, 35 ppm or more, 40 ppm or more, or 45 ppm or more. The higher the content of sodium atoms, the residue between wirings is less likely to occur.

The upper limit of sodium atoms included in the photosensitive resin composition layer which can be combined with the above lower limit is preferably 50 ppm or less, based on the total amount of the photosensitive resin composition layer. When the content of sodium atoms is the upper limit or less, the permeability of the developing solution and water washing water is moderate, and the resolution in dense patterns tends to be excellent.

The upper limit of the content of sodium atoms in the photosensitive resin composition layer which can be combined with the above lower limit may be 45 ppm or less, 40 ppm or less, 35 ppm or less, 30 ppm or less, 25 ppm or less, 20 ppm or less, 19 ppm or less, 18 ppm or less, 17 ppm or less, 16 ppm or less, 15 ppm or less, 9 ppm or less, 8 ppm or less, 7 ppm or less, 6 ppm or less, 5 ppm or less, 4 ppm or less, 3 ppm or less, or 2 ppm or less.

The content of sodium atoms in the photosensitive resin composition layer is more preferably 1 ppm or more and 50 ppm or less, still more preferably 1.5 ppm or more and 25 ppm or less, yet more preferably, and further preferably 2 ppm or more and 10 ppm or less, based on the total amount of the photosensitive resin composition layer. When the content of sodium atoms is within the above range, the formability of a dense wiring pattern is excellent in order to prevent the residue between the wirings and the patterns from coming into contact with each other.

Examples of means for adjusting the content of sodium atoms in the photosensitive resin composition layer to within the range of 1 ppm or more and 50 ppm or less include, but are not particularly limited, to various adjustments of the composition of the photosensitive resin composition with respect to each component, removal using an ion-exchange resin, or addition of various sodium salt compounds.

### (F) Sensitizer

The photosensitive resin composition layer may optionally include (F) a sensitizer. The sensitizer preferably includes at least one selected from the group consisting of pyrazoline compounds, anthracene compounds, triarylamine compounds and oxazole compounds. The reason for this is that these compounds strongly absorb light around 405 nm, which is called the h-line. Use of these compounds as sensitizers tends to improve the sensitivity and image-forming properties. Of these, the sensitizer more preferably includes at least one selected from pyrazoline compounds and anthracene compounds.

The amount of the sensitizer is preferably 0.005 to 2 wt % relative to the total weight of the solid content of the photosensitive resin composition layer. Good sensitivity, resolution and adhesion can be obtained by using the sensitizer in the amount within this range.

Any sensitizer may be used as long as the sensitivity is improved by using in combination with (C) a photopolymerization initiator. Examples of the function of the sensitizer include various functions of absorbing exposure wavelength light to impart energy or electrons to the photopolymerization initiator, promoting the cleavage of the photopolymerization initiator, and regenerating radicals through new cleavage and decomposition after migration of initiating radicals generated from the photopolymerization initiator or growing radicals once added to a monomer and polymerized to the sensitizer.

Examples of the sensitizers other than pyrazoline compounds, anthracene compounds, triarylamine compounds and oxazole compounds include N-aryl-α-amino acid compounds, aromatic ketone compounds substituted with an alkylamino group, dialkylaminobenzoic acid ester compounds, pyrazoline derivatives, anthracene derivatives, triphenylamine derivatives, ester compounds of N-arylamino acid, halogen compounds and the like.

Examples of N-aryl-α-amino acid compounds include N-phenylglycine, N-methyl-N-phenylglycine, N-ethyl-N-phenylglycine and the like. In particular, N-phenylglycine is preferable because of its high sensitizing effect. Examples of aromatic ketone compounds substituted with an alkylamino group include Michler's ketone[4,4′-bis(dimethylamino)benzophenone], 4,4′-bis(diethylamino)benzophenone, 4-methoxy-4′-dimethylaminobenzophenone and the like. Examples of dialkylaminobenzoic acid ester compounds include ethyl dimethylaminobenzoate, ethyl diethylaminobenzoate, ethyl-p-dimethylaminobenzoate, 2-ethylhexyl-4-(dimethylamino)benzoate and the like.

From the viewpoint of adhesion and rectangularity of the resist pattern, pyrazoline derivatives are preferably 5-(4-tert-butylphenyl)-3-(4-tert-butylstyryl)-1-phenyl-2-pyrazoline, 5-(4-tert-butylphenyl)-1-phenyl-3-(4-phenylphenyl)-4,5-dihydro-1H-pyrazole, 1-phenyl-3-(4-isopropylstyryl)-5-(4-isopropylphenyl)-pyrazoline, 1-phenyl-3-(4-tert-butyl-styryl)-5-(4-tert-butyl)-pyrazoline, 1-phenyl-3-(4-methoxystyryl)-5-(4-methoxyphenyl)-pyrazoline, 1-phenyl-3-(3,5-dimethoxystyryl)-5-(3,5-dimethoxyphenyl)-pyrazoline, 1-phenyl-3-(3,4-dimethoxystyryl)-5-(3,4-dimethoxyphenyl)-pyrazoline, 1-phenyl-3-(2,6-dimethoxystyryl)-5-(2,6-dimethoxyphenyl)-pyrazoline, 1-phenyl-3-(2,5-dimethoxystyryl)-5-(2,5-dimethoxyphenyl)-pyrazoline, 1-phenyl-3-(2,3-dimethoxystyryl)-5-(2,3-dimethoxyphenyl)-pyrazoline, 1-phenyl-3-(2,4-dimethoxystyryl)-5-(2,4-dimethoxyphenyl)-pyrazoline, 1-phenyl-3,5-bis(4-tert-butyl-phenyl)-pyrazoline, 1-phenyl-3,5-bis(4-methoxy-phenyl)-pyrazoline, 1-phenyl-3-(4-methoxy-phenyl)-5-(4-tert-butyl-phenyl)-pyrazoline, 1-phenyl-3-(4-tert-butyl-phenyl)-5-(4-methoxy-phenyl)-pyrazoline, 1-phenyl-3-(4-isopropyl-phenyl)-5-(4-tert-butyl-phenyl)-pyrazoline, 1-phenyl-3-(4-tert-butyl-phenyl)-5-(4-isopropyl-phenyl)-pyrazoline, 1-phenyl-3-(4-methoxy-phenyl)-5-(4-isopropyl-phenyl)-pyrazoline, 1-phenyl-3-(4-isopropyl-phenyl)-5-(4-methoxy-phenyl)-pyrazoline, 1,5-diphenyl-3-(4-tert-butyl-phenyl)-pyrazoline, 1,3-diphenyl-5-(4-tert-butyl-phenyl)-pyrazoline, 1,5-diphenyl-3-(4-isopropyl-phenyl)-pyrazoline, 1,3-diphenyl-5-(4-isopropyl-phenyl)-pyrazoline, 1,5-diphenyl-3-(4-methoxy-phenyl)-pyrazoline, 1,3-diphenyl-5-(4-methoxy-phenyl)-pyrazoline, 1-phenyl-3,5-bis(4-tert-butyl-phenyl)-pyrazoline, or 1,5-diphenyl-3-(4-tert-butyl-phenyl)-pyrazoline. Of these, 1-phenyl-3-(4-biphenyl)-5-(4-tert-butyl-phenyl)-pyrazoline and 1-phenyl-3-(4-biphenyl)-5-(4-tert-octyl-phenyl)-pyrazoline are preferable.

Anthracene compounds are preferably anthracene, 9,10-dialkoxyanthracene, 9,10-dimethoxy anthracene, 9, 10-diethoxyanthracene, or 9,10-dibutoxyanthracene. Of these, 9,10-dibutoxyanthracene is more preferable from the viewpoint of sensitivity. Examples of triarylamine compounds include compounds having a triphenylamine skeleton in the molecule. The triarylamine compound is preferably a compound represented by the following formula (2).

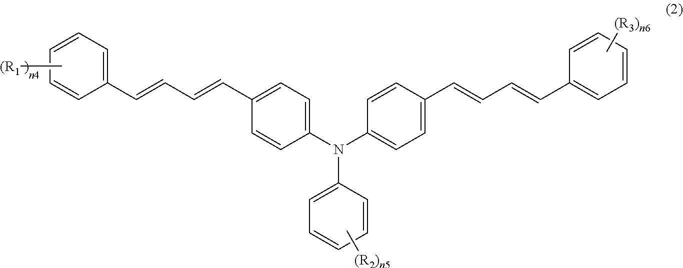

In the above formula (2), R₁, R₂ and R₃ each independently represent a linear or branched alkyl group having 1 to 10 carbon atoms or a linear or branched alkoxy group having 1 to 4 carbon atoms. n4, n5 and n6 represent an integer of 0 to 5 selected so that the value of n4+n5+n6 is 1 or more. When n4 is 2 or more, a plurality of R₁ may be the same or different, when n5 is 2 or more, a plurality of R₂ may be the same or different, and when n6 is 2 or more, a plurality of R₃ may be the same or different.

In the compound represented by the general formula (2), from the viewpoint of resolution and adhesion, it is preferable that R₂ is a linear or branched alkyl group having 1 to 10 carbon atoms, n4 and n6 are 0, and n5 is 1. It is more preferable that R₂ is a linear or branched alkyl group having 1 to 4 carbon atoms, n4 and n6 are 0, and n5 is 1.

Examples of the oxazole compound include compounds having an oxazole skeleton in the molecule. From the viewpoint of sensitivity, the oxazole compound is preferably 5-tert-butyl-2-[5-(5-tert-butyl-1,3-benzoxazol-2-yl)thiophen-2-yl]-1,3-benzoxazol or 2-[4-(1,3-benzoxazol-2-yl)naphthalen-1-yl]-1,3-benzoxazol.

Examples of the ester compound of N-arylamino acid include methyl ester of N-phenylglycine, ethyl ester of N-phenylglycine, n-propyl ester of N-phenylglycine, isopropyl ester of N-phenylglycine, 1-butyl ester of N-phenylglycine, 2-butyl ester of N-phenylglycine, tert-butyl ester of N-phenylglycine, pentyl ester of N-phenylglycine, hexyl ester of N-phenylglycine, pentyl ester of N-phenylglycine, octyl ester of N-phenylglycine and the like.

Examples of the halogen compound include amyl bromide, isoamyl bromide, isobutylene bromide, ethylene bromide, diphenylmethyl bromide, benzyl bromide, methylene bromide, tribromomethylphenylsulfone, carbon tetrabromide, tris(2,3-dibromopropyl)phosphate, trichloroacetamide, amyl iodide, isobutyl iodide, 1,1,1-trichloro-2,2-bis(p-chlorophenyl)ethane, chlorinated triazine compound, diallyliodonium compounds and the like. In particular, tribromomethylphenylsulfone is preferable.

### (G) Colorant

The photosensitive resin composition layer may optionally include a colorant. Examples of the colorant include dyes such as Fuchsine, Phthalocyanine Green, Auramine Base, Paramagenta, Crystal Violet, Methyl Orange, Nile Blue 2B, Victoria Blue, MALACHITE GREEN (e.g. Eisen (registered trademark) MALACHITE GREEN manufactured by Hodogaya Chemical Co., Ltd.), Basic Blue 20, DIAMOND GREEN (e.g., Eisen (registered trademark) DIAMOND GREEN GH manufactured by Hodogaya Chemical Co., Ltd.), 1,4-bis(4-methylphenylamino)-9,10-anthraquinone (e.g., OPLAS GREEN533 manufactured by Orient Chemical Industries Co., Ltd.), 1,4-bis(butylamino)anthraquinone (e.g., OIL BLUE 2N manufactured by Orient Chemical Industries Co., Ltd.), 1,4-bis(isopropylamino)-9,10-anthraquinone (e.g., OIL BLUE 630 manufactured by Orient Chemical Industries Co., Ltd.) and the like. Of these, Diamond Green is preferable as the colorant from the viewpoint of color developability. If the support film has good colorability, it is easy to visually detect the position of the film laminated on the base material, and there is also an advantage that errors in operations can be reduced in a series of patterning steps.

The photosensitive resin composition layer may include an oxide and/or a decomposition product of the colorant together with the colorant. The colorant oxides and/or decomposition product of the colorant may be sometimes formed due to the presence of the peroxide in the film. For example, when the colorant is Leuco Crystal Violet or Leucomalachite Green, 4-dimethylaminophenol may be sometimes produced, and when the colorant is Diamond Green, 4-diethylaminophenol may be sometimes produced. Therefore, the fact that the photosensitive resin composition layer includes the oxide and/or the decomposition product derived from the colorant strongly suggests that the coating solution of the photosensitive resin composition and the photosensitive resin composition layer formed therefrom also include the peroxide.

The dye may include Leuco dye or Fluoran dye. By containing them, the exposed area of the photosensitive resin composition layer develops color, which is preferable in view of the visibility. When an inspection machine or the like reads the alignment marker for exposure, It is advantageous to have a large contrast between the exposed and unexposed areas since it is easier to recognize.

Examples of the Leuco dye include tris(4-dimethylaminophenyl)methane [[Leuco Crystal Violet] and bis(4-dimethylaminophenyl)phenylmethane [Leuco Malachite Green]. In particular, Leuco Crystal Violet is preferably used as the Leuco dye from the viewpoint of good contrast.

The colorant preferably contains 0.01 to 1 part by weight of a dye based on 100 parts by weight of the alkali-soluble polymer. The pigment contained in the colorant is preferably 0 part by weight to 0.01 part by weight, or 0 part by weight to 0.001 part by weight, and it is more preferable that the colorant contains substantially no pigment (0 parts by weight).

The ratio of the colorant to the total amount of the photosensitive resin composition layer is preferably 0.01 to 10 wt %, more preferably 0.1 to 5 wt %, still more preferably 0.5 to 2 wt %, and particularly preferably is 0.5 to 1 wt %.

The content of the Leuco dye in the photosensitive resin composition layer is preferably 0.1 to 10 wt % relative to the total weight of the photosensitive resin composition layer. It is preferable that the content of the Leuco dye is 0.1 wt % or more from the viewpoint of improving the contrast between the exposed and unexposed areas. The content of the Leuco dye is more preferably 0.2 wt % or more, and still more preferably 0.4 wt % or more. The content of the Leuco dye is preferably 10 wt % or less from the viewpoint of maintaining the storage stability. The content of the Leuco dye is more preferably 2 wt % or less, and still more preferably 1 wt % or less.

Using the Leuco dye in combination of the halogen compound in the photosensitive resin composition layer is preferable from the viewpoint of optimizing the adhesion and contrast. The halogen compound can be derived from the above-mentioned organic halogen compound as the component (C), and tribromomethylphenylsulfone is particularly preferable.

### (H) Radical Polymerization Inhibitor

The photosensitive resin composition layer may optionally include a radical polymerization inhibitor. Examples of radical polymerization inhibitors include p-methoxyphenol, hydroquinone, pyrogallol, naphthylamine, tert-butylcatechol, cuprous chloride, 2,6-di-tert-butyl-p-cresol, 2,2′-methylenebis(4-methyl-6-tert-butylphenol), 2,2′-methylenebis(4-ethyl-6-tert-butylphenol), nitrosophenylhydroxyamine aluminum salt, diphenylnitrosamine and the like. A nitrosophenylhydroxyamine aluminum salt is preferable so as not to impair the sensitivity of the photosensitive resin composition layer.

Examples of benzotriazoles other than carboxylbenzotriazoles include 1,2,3-benzotriazole, 1-chloro-1,2,3-benzotriazole, bis(N-2-ethylhexyl)aminomethylene-1,2,3-benzotriazole, bis(N-2-ethylhexyl)aminomethylene-1,2,3-tolyltriazole, bis(N-2-hydroxyethyl)aminomethylene-1,2,3-benzotriazole and the like.

Examples of epoxy compounds of bisphenol A include compounds obtained by modifying bisphenol A with polypropylene glycol to epoxidize the ends.

The total content of the radical polymerization inhibitor, benzotriazoles other than carboxylbenzotriazoles, carboxylbenzotriazoles, and epoxy compounds of bisphenol A is preferably 0.001 to 3 wt %, and more preferably 0.01 to 1 wt %, relative to the total amount of the photosensitive resin composition layer. The content of 0.001 wt % or more is preferable from the viewpoint of imparting the storage stability to the photosensitive resin composition layer. The content of 3 wt % or less is preferable from the viewpoint of maintaining the sensitivity of the photosensitive resin composition layer and suppressing decolorization and color development of the dye.

### (I) Additives

In the present disclosure, “(I) Additives” are components mixed to give a desired function to the photosensitive resin composition layer, and refer to the above-mentioned components (A) to (H).

Additives (I) include carboxylbenzotriazoles from the viewpoint of preventing blushing of the substrate. Carboxylbenzotriazoles are included in an amount of 0.01 to 5 wt % relative to the total amount of the photosensitive resin composition layer. The amount of the additive is preferably 0.01 wt % or more from the viewpoint of preventing the substrate from blushing when the photosensitive resin multilayer body is laminated on a substrate such as a copper-clad multilayer body and developed after a certain period of time. The amount of additives added is more preferably 0.03 wt % or more, and still more preferably 0.05 wt % or more. The amount of additives is preferably 5 wt % or less from the viewpoint of obtaining high resolution. The amount of additives added is preferably 3 wt % or less, and more preferably 1 wt % or less.

Examples of carboxylbenzotriazoles include 4-carboxy-1,2,3-benzotriazole, 5-carboxy-1,2,3-benzotriazole, 1-[N,N-bis(2-ethylhexyl)aminomethyl]-5-carboxylbenzotriazole having an optionally substituted aminomethyl group, 1-[N,N-bis(2-ethylhexy)aminomethyl]-4-carboxylbenzotriazole, 1-[N,N-bis(isopropyl)aminomethyl]-5-carboxylbenzotriazole, 1-[N-hydro-N-3-(2-ethylhexyloxy)-1-propylaminomethyl]-5-carboxylbenzotriazole, 1-[N,N-bis(1-octyl)aminomethyl]-5-carboxylbenzotriazole, 1-[N,N-bis(2-hydrooxypropyl)aminomethyl]-5-carboxylbenzotriazole, 1-[N,N-bis(1-butyl)aminomethyl]-5-carboxylbenzotriazole and the like. Of these, 1-[N,N-bis(1-butyl)aminomethyl]-5-carboxylbenzotriazole is preferable from the viewpoint of anti-blushing performance. Regarding the substitution position of the carboxyl group, the 5-position and the 6-position may be mixed during the synthesis process, but both of them are preferable. It is possible to use, as carboxylbenzotriazole, for example, a 0.5:1.5 to 1.5:0.5 (weight ratio) mixture of 5- and 6-substituted compounds, particularly a 1:1 (weight ratio) mixture. It is sometimes simply referred to as “1-N-dibutylaminomethylcarboxylbenzotriazole” to indicate a mixture of 5- and 6-substituted compounds. It is also possible to use, as carboxylbenzotriazole, for example, compounds mentioned in JP 2008-175957 A. It is also possible to use 2-mercaptobenzoimidazole, 1H-tetrazole, 1-methyl-5-mercapto-1H-tetrazole, 2-amino-5-mercapto-1,3,4-thiadiazole, 3-amino-5-mercapto-1,2,4-triazole, 3-mercapto-1,2,4-triazole, 3-mercaptotriazole, 4,5-diphenyl-1,3-diazol-2-yl, 5-amino-1H-tetrazole and the like.

Examples of other additives which may be added as additives to the above-mentioned photosensitive resin composition layer include benzotriazoles other than carboxylbenzotriazoles, epoxy compounds of bisphenol A, and plasticizers.

Examples of plasticizers include phthalic acid esters such as diethyl phthalate, o-toluenesulfonic acid amide, p-toluenesulfonic acid amide, tributyl citrate, triethyl citrate, triethyl acetylcitrate, tri-n-propyl acetylcitrate, tri-n-butyl acetylcitrate, polyethylene glycol, polypropylene glycol, polyethylene glycol alkyl ether, polypropylene glycol alkyl ether and the like. Examples of plasticizers also include compounds having a bisphenol skeleton, such as ADEKA NOL SDX-1569, ADEKA NOL SDX-1570, ADEKA NOL SDX-1571 and ADEKA NOL SDX-479 (all of which are manufactured by Asahi Denka Co., Ltd.), NEWPOL BP-23P, NEWPOL BP-3P, NEWPOL BP-5P, NEWPOL BPE-20T, NEWPOL BPE-60, NEWPOL BPE-100 and NEWPOL BPE-180 (all of which are manufactured by SANYOKASEI CO., LTD.), Uniol DB-400, Uniol DAB-800, Uniol DA-350F, UNIOL DA- 400 and UNIOL DA-700 (all of which are manufactured by NOF Corporation), and BA-P4U Glycol and BA-P8 Glycol (all of which are manufactured by Nippon Nyukazai Co., Ltd.).

The content of the plasticizer relative to the total amount of the photosensitive resin composition layer is preferably 1 to 50 wt %, and more preferably 1 to 30 wt %. The content of the plasticizer is preferably 1 wt % or more from the viewpoint of suppressing the developing time delay and imparting the flexibility to the cured film. The content of the plasticizer is preferably 50 wt % or less from the viewpoint of preventing insufficient curing and cold flow.

### Support Film

The material for the support film is preferably a transparent material which transmits light emitted from an exposure light source. Examples of such support film include a polyethylene terephthalate film, a polyvinyl alcohol film, a polyvinyl chloride film, a vinyl chloride copolymer film, a polyvinylidene chloride film, a vinylidene chloride copolymer film, a polymethyl methacrylate copolymer film, a polystyrene film, a polyacrylonitrile film, a styrene copolymer film, a polyamide film, a cellulose derivative film and the like. These films may be stretched if necessary, and preferably have a haze of 5 or less. The smaller the thickness of the film, the more it is advantageous for the purpose of improving the image-forming properties and economic efficiency. To maintain the strength of the photosensitive resin multilayer body, a film having a thickness of 10 to 30 μm is preferably used.

### Protective Layer

The photosensitive resin multilayer body may have a protective layer on the surface opposite the support film side of the photosensitive resin composition layer. When the photosensitive resin multilayer body has the protective layer, it is preferable that the protective layer has sufficiently smaller adhesion to the photosensitive resin composition layer than the support film and can be easily stripped. For example, a polyethylene film or a polypropylene film is preferable as the protective layer. It is also possible to use a film having excellent strippability mentioned in, for example, JP 59-202457 A. The thickness of the protective layer is preferably 10 to 100 μm, and more preferably 10 to 50 μm.

When polyethylene is used for the protective layer, there is gel called fish eyes on the surface of the polyethylene film, which may be sometimes transferred to the photosensitive resin composition layer. If fish eyes are transferred to the photosensitive resin composition layer, air may be entrapped during lamination to form voids, leading to defects in the resist pattern. From the viewpoint of preventing fish eyes, the material of the protective layer is preferably oriented polypropylene. Specific examples thereof include ALPHAN E-200A manufactured by OJI PAPER CO., LTD.

The thickness of the photosensitive resin composition layer in the photosensitive resin multilayer body varies depending on applications, but is preferably 5 μm to 100 μm, and more preferably 7 μm to 60 μm. The thinner the layer, the more the resolution is improved. The thicker the layer, the more the film strength is improved.

### Method for Producing Photosensitive Resin Multilayer Body

The method for producing a photosensitive resin multilayer body according to the present disclosure comprises a step of preparing a coating solution containing a photosensitive resin composition, and a step of applying the coating solution on a support film and drying the coating solution to form a photosensitive resin composition layer. When using a protective layer, the method may further comprise laminating the protective layer on the photosensitive resin composition layer.

The content of acetone peroxide and/or methyl ethyl ketone peroxide in the photosensitive resin composition layer is 0.01 ppm or more and 1,000 ppm or less, based on the photosensitive resin composition layer. The content of the peroxide can be adjusted by adjusting the amount of acetone peroxide and/or methyl ethyl ketone peroxide contained in the coating solution, drying conditions of the coating solution and the like.

A known method can be adopted as a method for preparing the coating solution. For example, the photosensitive resin composition used for forming the photosensitive resin composition layer can be mixed with a solvent which dissolves them so as to obtain a uniform solution (coating solution).

Examples of suitable solvent include ketones such as acetone and methyl ethyl ketone (MEK); and alcohols such as methanol, ethanol and isopropyl alcohol. It is preferable to add the solvent to the photosensitive resin composition so as to adjust the viscosity of the coating solution of the photosensitive resin composition to 500 mPa·sec to 4,000 mPa·sec at 25° C.

The coating solution of this photosensitive resin composition is first applied on the support film using a bar coater or a roll coater, and then dried to laminate a photosensitive resin composition layer composed of the photosensitive resin composition on the support film. Then, if necessary, a protective layer can be laminated on the photosensitive resin composition layer to fabricate a photosensitive resin multilayer body.

### Method for Forming Resist Pattern

The present disclosure also provides a method for forming a resist pattern, the method comprising the steps of laminating the above-mentioned photosensitive resin multilayer body on a substrate, exposing and developing the photosensitive resin multilayer body laminated on the substrate. Examples of the resist pattern include resist patters formed on circuit boards (printed wiring boards), flexible boards, lead frame boards, chip on film (COF) boards, semiconductor package boards, transparent electrodes for liquid crystal panels, TFT wiring for liquid crystal panels, wirings for organic EL displays, plasma display panel (PDP) electrodes and the like. An example of the method for forming a resist pattern using a photosensitive resin multilayer body will be described below.

The method for forming a resist pattern comprises a step of laminating a photosensitive resin multilayer body on a substrate, a step of exposing the photosensitive resin composition layer, and a step of developing the exposed photosensitive resin composition layer.

### (1) Lamination Step

When there is a protective layer on the photosensitive resin composition layer, while stripping the protective layer, the photosensitive resin multilayer body is closely adhered on a substrate such as a copper-clad multilayer body or a flexible substrate using a hot roll laminator. The lamination conditions may be appropriately set at conventionally known conditions.

### (2) Exposure Step

A mask film having a desired pattern (e.g., a wiring pattern) is closely adhered on the support film of the photosensitive resin multilayer body, followed by exposure with an active light source, or a drawing pattern corresponding to the desired pattern is exposed by direct drawing Exposure is preferably carried out by direct writing of the writing pattern. It is possible to appropriately use, as the exposure wavelength, i-line, h-line, g-line, a mixture thereof or the like. The photosensitive resin composition layer is advantageous in that high sensitivity and high resolution can be realized in i-line or h-line exposure, particularly h-line exposure, and is particularly useful in direct drawing. The exposure conditions may be appropriately set at conventionally known conditions.

### (3) Development Step

After exposure, the support film on the photosensitive resin composition layer is stripped, and then the unexposed area is developed and removed using an aqueous alkali solution as a developing solution to form a resist pattern on the substrate. An aqueous solution of Na₂CO₃ or K₂CO₃ is used as the aqueous alkali solution. The aqueous alkali solution is appropriately selected according to the properties of the photosensitive resin composition layer, but is usually an aqueous solution of Na₂CO₃ having a concentration of about 0.2 to 2% by weight and a temperature of about 20 to 40° C.

A resist pattern can be obtained through each of the above steps, and in some cases, a heating step at about 100 to 300° C. can also be carried out. By carrying out this heating step, it becomes possible to further improve the chemical resistance. A hot air, infrared or far infrared heating furnace can be used for heating.

The method for forming a metal wiring comprises a step of forming a resist pattern by the above method, a step of forming a metal wiring (conductor pattern) using the resist pattern, and a step of removing the resist pattern.

### Method for Producing Circuit Board

The present disclosure also provides a method for producing a circuit board, comprising the steps of laminating the above-mentioned photosensitive resin multilayer body on a substrate, and exposing, developing and plating the photosensitive resin multilayer body laminated on the substrate, and a method of producing a circuit board, comprising the steps of laminating the multilayer body on a substrate, and exposing, developing and etching the photosensitive resin multilayer body laminated on the substrate. The circuit board can be produced by further etching or plating the substrate on which the resist pattern is formed by the above-mentioned procedure for the method for forming a resist pattern. In particular, exposure by direct drawing of a drawing pattern in the production of a circuit board is advantageous from the viewpoint of productivity, because there is no need to fabricate a mask. Etching and plating each can be carried out as follows.

### (4) Etching Step or Plating Step

The surface of the substrate exposed by the above-mentioned development (e.g., copper surface in the case of a copper-clad multilayer body) undergoes etching or plating to form a conductor pattern. It is possible appropriately use, as etching and plating methods, conventionally known methods.

### (5) Removing Step

Thereafter, the resist pattern is removed from the substrate with an aqueous solution having stronger alkalinity than that of the developing solution. There is no particular limitation on the aqueous alkali solution for removing, but an aqueous solution of NaOH or KOH having a concentration of about 2 to 5% by weight and a temperature of about 40 to 70° C. is generally used. A small amount of water-soluble solvent can also be added to the removing solution. By using a diphenylpyrazoline derivative as the sensitizer (F), particularly excellent removability after plating is obtained. A circuit board can be produced by the above procedure.

The method for producing a semiconductor package comprises a step of forming a resist pattern on a semiconductor package substrate as a base material by the above-mentioned resist pattern forming method, and a step of etching or plating the semiconductor package substrate on which the resist pattern is formed. It is possible to appropriately adopt, as the structure of the semiconductor package substrate and the semiconductor package, conventionally known arbitrary structures. Formation of the resist pattern, and etching or plating can be carried out according to the procedures as mentioned above.

As mentioned above, according to the present disclosure, it is possible to provide a photosensitive resin multilayer body capable of achieving both solubility in a developing solution, i.e., developability, and adhesion to a substrate, particularly a copper substrate, and a method for producing the same.

### EXAMPLES

A description will be made of a method for measuring values for physical properties of polymers and monomers, and a method for fabricating samples for evaluation of Examples (Ex.) and Comparative Examples (Comp.Ex.). Then, a method for evaluating the obtained samples and the evaluation results are shown.

### Measurement or Calculation of Values for Physical Properties

### Measurement of Weight-Average Molecular Weight or Number-Average Molecular Weight of Polymer

The weight-average molecular weight or number-average molecular weight of a polymer was determined as polystyrene equivalent by gel permeation chromatography (GPC) manufactured by JASCO Corporation (pump: Gulliver, PU-1580 type, column: Shodex (registered trademark) manufactured by Showa Denko K.K. (KF-807, KF-806M, KF-806M, KF-802.5) 4 columns in series, mobile phase solvent: tetrahydrofuran, polystyrene standard sample (using a calibration curve based on Shodex STANDARD SM-105 manufactured by Showa Denko K.K.).

Furthermore, the degree of dispersibility of the polymer was calculated as a ratio of the weight-average molecular weight to the number-average molecular weight (weight-average molecular weight/number-average molecular weight).

### Acid Equivalent

As used herein, the acid equivalent means the weight (gram) of a polymer having one equivalent of carboxyl groups in the molecule. Using Hiranuma Automatic Titrator (COM-555) manufactured by Hiranuma Sangyo Co., Ltd., the acid equivalent was measured by the potentiometric titration method using an aqueous 0.1 mol/L sodium hydroxide solution.

Content of Acetone Peroxide and/or Methyl Ethyl Ketone Peroxide

The content of acetone peroxide or methyl ethyl ketone peroxide of the photosensitive resin composition layer was measured by gas chromatography (GC). Measurement conditions are shown below.

### (1) Apparatus

Gas chromatography (GC): 6890N network GC system (manufactured by Agilent Technologies Inc.)

### (2) Pretreatment

### Preparation of Internal Standard Solution:

After weighing about 0.3 g of propylene glycol monomethyl ether (PGME) as a standard solution in a 100 ml volumetric flask, the weight was precisely measured. Cyclohexanone was added to make the total volume of 100 ml. The amount of PGME charged therein was used as a factor.

### Fabrication of Masterbatch for Calibration Curve:

After weighing about 10 g of cyclohexanone in a 30 ml screw bottle, the weight is precisely measured. After weighing about 0.4 g of MEK peroxide or acetone peroxide, the weight is precisely measured.

### Fabrication of Calibration Curve Samples:

Three 30 ml screw bottles were prepared, followed by the addition in the following manner.
1) 10 ml of cyclohexanone (10 ml whole pipette)
2) 2 ml of PGME internal standard solution (2 ml whole pipette)
3) The calibration curve masterbatch was accurately weighed according to the following.
Calibration curve 1: about 50 mg
Calibration curve 2: about 100 mg
Calibration curve 3: about 150 mg

### Fabrication of Measurement Samples:

A 30 ml screw bottle was prepared, followed by the addition in the following manner and further dissolution of a resist on shaking.
1) 10 ml of cyclohexanone (10 ml whole pipette)
2) 2 ml of internal standard solution (2 ml whole pipette)
3) 16 cm×15 cm photosensitive resin composition layer having a thickness of 25 μm (weight was precisely measured)

### GC Measurement:

The measurement samples obtained by the above operations were measured by the GC method to determine the content of MEK peroxide and/or acetone peroxide in the photosensitive resin composition layer.

### Examples and Comparative Examples

### Fabrication of Photosensitive Resin Multilayer Body

Coating solutions of photosensitive resin compositions (Cmp.) 1 to 42 were prepared according to the formulations shown in Tables 4 to 8. Each of the coating solutions thus obtained was applied to a polyethylene terephthalate film (FB-40, manufactured by Toray Industries, Inc.) having a thickness of 16 μm and then dried in a drying oven at 95° C. for 3 minutes to form a photosensitive resin composition layer having a thickness of 25 μm after drying. A 19 μm thick polyethylene film (GF-818, manufactured by TAMAPOLY CO., LTD.) was laminated on the photosensitive resin composition layer to obtain a photosensitive resin multilayer body in which a support, a photosensitive layer and a protective layer were laminated in order.

### Surface Cleaning and Conditioning of Substrate

An abrasive (Sakurandom R (registered trademark #220) manufactured by Japan Carlit Co., Ltd.) was sprayed over a 0.4 mm thick copper-clad laminate obtained by being laminated with a 35 μm rolled copper foil under a spray pressure of 0.2 MPa to polish the surface. Lamination

While stripping a polyethylene film of the photosensitive resin multilayer body, the photosensitive resin multilayer body was laminated on a copper-clad laminate preheated to 60° C. by a hot roll laminator (AL-700, manufactured by Asahi Kasei Co., Ltd.) at a roll temperature of 105° C. The air pressure was set at 0.35 MPa and the lamination speed was set at 1.5 m/min.

### Exposure

Each of the photosensitive resin multilayer composition bodies fabricated using compositions 1 to 5 and 20 to 24 was exposed using a direct writing exposure machine (DE-1DH manufactured by Via Mechanics, Ltd., light source: GaN blue-violet diode, dominant wavelength of 405±5 nm) at an illuminance of 85 mW/cm² and 60 mJ/cm². Each of the photosensitive resin multilayer composition bodies fabricated using compositions 6 to 19 and 25 to 42 was exposed at an exposure dose of 160 mJ/cm² using a parallel light exposure machine (HMW-801 manufactured by ORC MANUFACTURING CO., LTD.).

### Development

After stripping the polyethylene terephthalate film of the exposed evaluation substrate, an aqueous 1 wt % Na₂CO₃ solution at 30° C. was sprayed for a predetermined time using an alkali developing machine (dry film developing machine manufactured by FUJI KIKO CO., LTD.) to develop and dissolve the unexposed area of the photosensitive resin composition layer. At this time, development was carried out for twice the minimum developing time to prepare a cured resist portion. The minimum developing time is the shortest time required for the unexposed area of the photosensitive resin composition layer to completely dissolve.

### Method for Evaluation of Developability

After laminating a photosensitive resin multilayer body on a substrate, the minimum developing time was measured after 15 minutes, and then evaluation was carried out according to the following criteria. Criteria E was rejected.
A: The minimum developing time was less than 17 seconds;
B: The minimum developing time was 17 seconds or more and less than 19 seconds;
C: The minimum developing time was 19 seconds or more and less than 21 seconds;
D: The minimum developing time was 21 seconds or more and less than 25 seconds;
E: The minimum developing time was 25 seconds or more.

### Method for Evaluation of Post-Exposure Color Developability

A photosensitive resin multilayer body was laminated on a substrate, and after 15 minutes, exposure was carried out under the above exposure conditions, and the pattern after exposure was visually observed according to the following criteria. Evaluation was carried out and criteria E was rejected.
A: The pattern after exposure was visually recognizable clearly;
B: The pattern after exposure was somewhat visually recognizable;
C: The pattern after exposure was visually recognizable slightly;
D: The pattern after exposure was visually recognizable with difficulty;
E: The pattern after exposure could not be visually recognized at all.

### Method for Evaluation of Colorability of Support Film

A photosensitive resin multilayer body was laminated on a substrate, and after 15 minutes, a support film was visually observed and evaluated according to the following criteria, and criteria E was rejected.
A: The colorability of the support film was visually recognizable clearly;
B: The colorability of the support film was somewhat visually recognizable;
C: The colorability of the support film was visually recognizable slightly;
D: The colorability of the support film was visually recognizable with difficulty;
E: The colorability of the support film could not be visually recognized at all.

Explanations of materials used in Examples and Comparative Examples are shown in Tables 1 to 3, and formulations and evaluation results are shown in Tables 4 to 8. As described in Tables 1 and 2, each alkali-soluble polymer (A) was used after being dissolved in the mixed solvent mentioned in the column “Solvent ratio (weight ratio)” at the concentration mentioned in the column “Concentration (wt %)”. In Tables 4 to 8, the content of the peroxide (D) is expressed by ppm, and the amount of each of other materials is expressed as parts by weight. The parts by weight of the alkali-soluble polymer (A) are expressed as parts by weight of the alkali-soluble polymer itself excluding the weight of the solvent. “Solvent” in Tables 4 to 8 indicates a solvent additionally added in addition to the solvent contained in the alkali-soluble polymer solution. In Example 39, it was observed that the photosensitive resin composition layer includes at least 4-dimethylaminophenol. In Example 40, it was observed that the photosensitive resin composition layer includes at least 4-diethylaminophenol.

TABLE 1

| | | | Weight- | | |
|---|---|---|---|---|---|
| | | | average | | |
| | | Acid | molecular | Concentration | Solvent ratio |
| Symbol | Explanation | equivalent | weight | (wt %) | (weight ratio) |
| A-1 | Methacrylic acid/benzyl | 430 | 50,000 | 49.5 | MEK:ethanol = |
| | methacrylate = 20/80 | | | | 75:25 |
| A-2 | Methacrylic acid/benzyl | 430 | 50,000 | 49.5 | MEK:ethanol = |
| | methacrylate = 20/80 | | | | 75:25 |
| A-3 | Methacrylic acid/benzyl | 430 | 50,000 | 49.5 | MEK:ethanol = |
| | methacrylate = 20/80 | | | | 75:25 |
| A-4 | Methacrylic acid/benzyl | 430 | 50,000 | 49.5 | MEK:ethanol = |
| | methacrylate = 20/80 | | | | 75:25 |
| A-5 | Methacrylic acid/benzyl | 430 | 50,000 | 49.5 | MEK:ethanol = |
| | methacrylate = 20/80 | | | | 75:25 |
| A-6 | Methacrylic acid/styrene/benzyl | 290 | 55000 | 41 | MEK:ethanol = |
| | methacrylate = 30/20/50 | | | | 75:25 |
| A-7 | Methacrylic acid/styrene/benzyl | 290 | 55000 | 41 | MEK:ethanol = |
| | methacrylate = 30/20/50 | | | | 75:25 |
| A-8 | Methacrylic acid/styrene/benzyl | 290 | 55,000 | 41 | MEK:ethanol = |
| | methacrylate = 30/20/50 | | | | 75:25 |
| A-9 | Methacrylic acid/styrene/benzyl | 290 | 55,000 | 41 | MEK:ethanol = |
| | methacrylate = 30/20/50 | | | | 75:25 |
| A-10 | Methacrylic acid/2-ethylhexyl | 290 | 50,000 | 40 | MEK:ethanol = |
| | acrylate/styrene/2-hydroxyethyl | | | | 75:25 |
| | methacrylate = 30/20/40/10 | | | | |
| A-11 | Methacrylic acid/2-ethylhexyl | 290 | 50,000 | 40 | MEK:ethanol = |
| | acrylate/styrene/2-hydroxyethyl | | | | 75:25 |
| | methacrylate = 30/20/40/10 | | | | |
| A-12 | Methacrylic acid/2-ethylhexyl | 290 | 50,000 | 40 | MEK:ethanol = |
| | acrylate/styrene/2-hydroxyethyl | | | | 75:25 |
| | methacrylate = 30/20/40/10 | | | | |
| A-13 | Methacrylic acid/2-ethylhexyl | 290 | 50,000 | 40 | MEK:ethanol = |
| | acrylate/styrene/2-hydroxyethyl | | | | 75:25 |
| | methacrylate = 30/20/40/10 | | | | |
| A-14 | Methacrylic acid/styrene/methyl | 344 | 50,000 | 44.5 | MEK:ethanol = |
| | methacrylate = 25/25/50 | | | | 75:25 |
| A-15 | Methacrylic acid/styrene/methyl | 344 | 50,000 | 44.5 | MEK:ethanol = |
| | methacrylate = 25/25/50 | | | | 75:25 |
| A-16 | Methacrylic acid/styrene/methyl | 344 | 50,000 | 44.5 | MEK:ethanol = |
| | methacrylate = 25/25/50 | | | | 75:25 |
| A-17 | Methacrylic acid/styrene/methyl | 344 | 50,000 | 44.5 | MEK:ethanol = |
| | methacrylate = 25/25/50 | | | | 75:25 |

TABLE 2

| | | | Weight- | | |
|---|---|---|---|---|---|
| | | | average | | |
| | | Acid | molecular | Concentration | Solvent ratio |
| Symbol | Explanation | equivalent | weight | (wt %) | (weight ratio) |
| A-18 | Methacrylic acid/benzyl | 430 | 50,000 | 49.5 | Acetone:ethanol = |
| | methacrylate = 20/80 | | | | 75:25 |
| A-19 | Methacrylic acid/benzyl | 430 | 50,000 | 49.5 | Acetone:ethanol = |
| | methacrylate = 20/80 | | | | 75:25 |
| A-20 | Methacrylic acid/benzyl | 430 | 50,000 | 49.5 | Acetone:ethanol = |
| | methacrylate = 20/80 | | | | 75:25 |
| A-21 | Methacrylic acid/benzyl | 430 | 50,000 | 49.5 | Acetone:ethanol = |
| | methacrylate = 20/80 | | | | 75:25 |
| A-22 | Methacrylic acid/benzyl | 430 | 50,000 | 49.5 | Acetone:ethanol = |
| | methacrylate = 20/80 | | | | 75:25 |
| A-23 | Methacrylic acid/styrene/benzyl | 290 | 55,000 | 41 | Acetone:ethanol = |
| | methacrylate = 30/20/50 | | | | 75:25 |
| A-24 | Methacrylic acid/styrene/benzyl | 290 | 55,000 | 41 | Acetone:ethanol = |
| | methacrylate = 30/20/50 | | | | 75:25 |
| A-25 | Methacrylic acid/styrene/benzyl | 290 | 55,000 | 41 | Acetone:ethanol = |
| | methacrylate = 30/20/50 | | | | 75:25 |
| A-26 | Methacrylic acid/styrene/benzyl | 290 | 55,000 | 41 | Acetone:ethanol = |
| | methacrylate = 30/20/50 | | | | 75:25 |
| A-27 | Methacrylic acid/2-ethylhexyl | 290 | 50,000 | 40 | Acetone:ethanol = |
| | acrylate/styrene/2-hydroxyethyl | | | | 75:25 |
| | methacrylate = 30/20/40/10 | | | | |
| A-28 | Methacrylic acid/2-ethylhexyl | 290 | 50,000 | 40 | Acetone:ethanol = |
| | acrylate/styrene/2-hydroxyethyl | | | | 75:25 |
| | methacrylate = 30/20/40/10 | | | | |
| A-29 | Methacrylic acid/2-ethylhexyl | 290 | 50,000 | 40 | Acetone:ethanol = |
| | acrylate/styrene/2-hydroxyethyl | | | | 75:25 |
| | methacrylate = 30/20/40/10 | | | | |
| A-30 | Methacrylic acid/2-ethylhexyl | 290 | 50,000 | 40 | Acetone:ethanol = |
| | acrylate/styrene/2-hydroxyethyl | | | | 75:25 |
| | methacrylate = 30/20/40/10 | | | | |
| A-31 | Methacrylic acid/styrene/methyl | 344 | 50,000 | 44.5 | Acetone:ethanol = |
| | methacrylate = 25/25/50 | | | | 75:25 |
| A-32 | Methacrylic acid/styrene/methyl | 344 | 50,000 | 44.5 | Acetone:ethanol = |
| | methacrylate = 25/25/50 | | | | 75:25 |
| A-33 | Methacrylic acid/styrene/methyl | 344 | 50,000 | 44.5 | Acetone:ethanol = |
| | methacrylate = 25/25/50 | | | | 75:25 |
| A-34 | Methacrylic acid/styrene/methyl | 344 | 50,000 | 44.5 | Acetone:ethanol = |
| | methacrylate = 25/25/50 | | | | 75:25 |

TABLE 3

| Symbol | Explanation |
|---|---|
| B-1 | Dimethacrylate of polyethylene glycol in which each of 5 mols on average of |
| | ethylene oxide is added to both ends of bisphenol A (BPE-500, product name, |
| | manufactured by SHIN-NAKAMURA CHEMICAL CO, LTD.) |
| B-2 | Tetramethacrylate in which 15 mols on average of ethylene oxide are added to |
| | pentaerythritol |
| B-3 | 7:3 Mixture of pentaerythritol triacrylate and pentaerythritol tetraacrylate (M-306, |
| | product name, manufactured by TOAGOSEI CO., LTD.) |
| B-4 | Dimethacrylate of polyalkylene glycol in which each of 3 mols on average of |
| | ethylene oxide is further added to polypropylene glycol to which 12 mols on average |
| | of propylene oxide are added |
| C-1 | 2-(O-chlorophenyl)-4,5-diphenylimidazole dimer |
| C-2 | 1-Phenyl-3-(4-bipheny1)-5-(4-tert-butyl-phenyl)-pyrazoline |
| C-3 | 4,4′-Bis(diethylamino)benzophenone |
| D-1 | Methyl ethyl ketone peroxide |
| D-2 | Acetone peroxide |
| G-1 | Leuco Crystal Violet |
| G-2 | Diamond Green |
| H-1 | p-Methoxyphenol |

TABLE 4

| | | Ex. 1 | Ex. 2 | Ex. 3 | Ex. 4 | Ex. 5 | Ex. 6 | Ex. 7 | Ex. 8 | Ex. 9 | Ex. 10 | Ex. 11 |
|---|---|---|---|---|---|---|---|---|---|---|---|---|
| | | Cmp. 1 | Cmp. 2 | Cmp. 3 | Cmp. 4 | Cmp. 5 | Cmp. 6 | Cmp. 7 | Cmp. 8 | Cmp. 9 | Cmp. 10 | Cmp. 11 |
| (A) Alkali-soluble | A-1 | 101 | | | | | | | | | | |
| polymer | A-2 | | 101 | | | | | | | | | |
| | A-3 | | | 101 | | | | | | | | |
| | A-4 | | | | 101 | | | | | | | |
| | A-5 | | | | | 101 | | | | | | |
| | A-6 | | | | | | 73 | 73 | 73 | | | |
| | A-7 | | | | | | | | | 73 | 73 | 73 |
| | A-10 | | | | | | 50 | | | | | |
| | A-11 | | | | | | | 50 | | 50 | | |
| | A-12 | | | | | | | | 50 | | 50 | |
| | A-13 | | | | | | | | | | | 50 |
| (B) Monomer | B-1 | 20 | 20 | 20 | 20 | 20 | | | | | | |
| | B-2 | 15 | 15 | 15 | 15 | 15 | | | | | | |
| | B-3 | | | | | | 20 | 20 | 20 | 20 | 20 | 20 |
| | B-4 | | | | | | 15 | 15 | 15 | 15 | 15 | 15 |
| (C) | C-1 | 5 | 5 | 5 | 5 | 5 | 3 | 3 | 3 | 3 | 3 | 3 |
| Photopolymerization | C-2 | 0.2 | 0.2 | 0.2 | 0.2 | 0.2 | | | | | | |
| initiator | C-3 | | | | | | 0.2 | 0.2 | 0.2 | 0.2 | 0.2 | 0.2 |
| (D) Peroxide | D-1 (ppm) | 3 | 67 | 134 | 356 | 679 | 4 | 77 | 179 | 147 | 249 | 470 |
| | D-2 (ppm) | 0 | 0 | 0 | 0 | 0 | 0 | 0 | 0 | 0 | 0 | 0 |
| | Total amount | 3 | 67 | 134 | 356 | 679 | 4 | 77 | 179 | 147 | 249 | 470 |
| | of peroxide | | | | | | | | | | | |
| (G) Colorant | G-1 | 0.5 | 0.5 | 0.5 | 0.5 | 0.5 | 0.5 | 0.5 | 0.5 | 0.5 | 0.5 | 0.5 |
| | G-2 | 0.05 | 0.05 | 0.05 | 0.05 | 0.05 | 0.05 | 0.05 | 0.05 | 0.05 | 0.05 | 0.05 |
| Solvent | MEK | 15 | 15 | 15 | 15 | 15 | 15 | 15 | 15 | 15 | 15 | 15 |
| | Total solid | 90.745 | 90.745 | 90.745 | 90.745 | 90.745 | 88.68 | 88.68 | 88.68 | 88.68 | 88.68 | 88.68 |
| | content | | | | | | | | | | | |
| Evaluation | Developability | A | A | A | B | C | A | A | A | A | A | B |
| | Post-exposure | D | C | C | C | B | D | C | C | C | C | C |
| | color | | | | | | | | | | | |
| | developability | | | | | | | | | | | |
| | Support film | A | A | C | C | C | A | A | C | C | C | C |
| | colorability | | | | | | | | | | | |

TABLE 5

| | | Ex. 12 | Ex. 13 | Ex. 14 | Ex. 15 | Ex. 16 | Ex. 17 | Ex. 18 | Ex. 19 |
|---|---|---|---|---|---|---|---|---|---|
| | | Cmp. 12 | Cmp. 13 | Cmp. 14 | Cmp. 15 | Cmp. 16 | Cmp. 17 | Cmp. 18 | Cmp. 19 |
| (A) Alkali-soluble | A-8 | 73 | | | | | | | |
| polymer | A-9 | | 73 | 73 | 73 | | | | |
| | A-10 | 50 | 50 | | | | | | |
| | A-12 | | | 50 | | | | | |
| | A-13 | | | | 50 | | | | |
| | A-14 | | | | | 112 | | | |
| | A-15 | | | | | | 112 | | |
| | A-16 | | | | | | | 112 | |
| | A-17 | | | | | | | | 112 |
| (B) Monomer | B-3 | 20 | 20 | 20 | 20 | 20 | 20 | 20 | 20 |
| | B-4 | 15 | 15 | 15 | 15 | 15 | 15 | 15 | 15 |
| (C) Photopolymerization | C-1 | 3 | 3 | 3 | 3 | 3 | 3 | 3 | 3 |
| initiator | C-3 | 0.2 | 0.2 | 0.2 | 0.2 | 0.2 | 0.2 | 0.2 | 0.2 |
| (D) Peroxide | D-1 (ppm) | 207 | 430 | 604 | 825 | 5 | 101 | 305 | 912 |
| | D-2 (ppm) | 0 | 0 | 0 | 0 | 0 | 0 | 0 | 0 |
| | Total amount of peroxide | 207 | 430 | 604 | 825 | 5 | 101 | 305 | 912 |
| (G) Colorant | G-1 | 0.5 | 0.5 | 0.5 | 0.5 | 0.5 | 0.5 | 0.5 | 0.5 |
| | G-2 | 0.05 | 0.05 | 0.05 | 0.05 | 0.05 | 0.05 | 0.05 | 0.05 |
| Solvent | MEK | 15 | 15 | 15 | 15 | 15 | 15 | 15 | 15 |
| | Total solid content | 88.68 | 88.68 | 88.68 | 88.68 | 88.59 | 88.59 | 88.59 | 88.59 |
| Evaluation | Developability | A | B | C | D | A | A | B | D |
| | Post-exposure color developability | C | C | B | A | D | C | C | A |
| | Support film colorability | C | C | C | D | A | C | C | D |

TABLE 6

| | | Ex. 20 | Ex. 21 | Ex. 22 | Ex. 23 | Ex. 24 | Ex. 25 | Ex. 26 | Ex. 27 | Ex. 28 | Ex. 29 | Ex. 30 |
|---|---|---|---|---|---|---|---|---|---|---|---|---|
| | | Cmp. 20 | Cmp. 21 | Cmp. 22 | Cmp. 23 | Cmp. 24 | Cmp. 25 | Cmp. 26 | Cmp. 27 | Cmp. 28 | Cmp. 29 | Cmp. 30 |
| (A) Alkali- | A-18 | 101 | | | | | | | | | | |
| soluble | A-19 | | 101 | | | | | | | | | |
| polymer | A-20 | | | 101 | | | | | | | | |
| | A-21 | | | | 101 | | | | | | | |
| | A-22 | | | | | 101 | | | | | | |
| | A-23 | | | | | | 73 | 73 | 73 | | | |
| | A-24 | | | | | | | | | 73 | 73 | 73 |
| | A-27 | | | | | | 50 | | | | | |
| | A-28 | | | | | | | 50 | | 50 | | |
| | A-29 | | | | | | | | 50 | | 50 | |
| | A-30 | | | | | | | | | | | 50 |
| (B) Monomer | B-1 | 20 | 20 | 20 | 20 | 20 | | | | | | |
| | B-2 | 15 | 15 | 15 | 15 | 15 | | | | | | |
| | B-3 | | | | | | 20 | 20 | 20 | 20 | 20 | 20 |
| | B-4 | | | | | | 15 | 15 | 15 | 15 | 15 | 15 |
| (C) | C-1 | 5 | 5 | 5 | 5 | 5 | 3 | 3 | 3 | 3 | 3 | 3 |
| Photo- | C-2 | 0.2 | 0.2 | 0.2 | 0.2 | 0.2 | | | | | | |
| polymerization | C-3 | | | | | | 0.2 | 0.2 | 0.2 | 0.2 | 0.2 | 0.2 |
| initiator | | | | | | | | | | | | |
| (D) Peroxide | D-1 (ppm) | 0 | 0 | 0 | 0 | 0 | 0 | 0 | 0 | 0 | 0 | 0 |
| | D-2 (ppm) | 2 | 89 | 234 | 445 | 913 | 4 | 49 | 201 | 99 | 251 | 404 |
| | Total amount | 2 | 89 | 234 | 445 | 913 | 4 | 49 | 201 | 99 | 251 | 404 |
| | of peroxide | | | | | | | | | | | |
| (G) Colorant | G-1 | 0.5 | 0.5 | 0.5 | 0.5 | 0.5 | 0.5 | 0.5 | 0.5 | 0.5 | 0.5 | 0.5 |
| | G-2 | 0.05 | 0.05 | 0.05 | 0.05 | 0.05 | 0.05 | 0.05 | 0.05 | 0.05 | 0.05 | 0.05 |
| Solvent | MEK | 15 | 15 | 15 | 15 | 15 | 15 | 15 | 15 | 15 | 15 | 15 |
| | Total | 90.745 | 90.745 | 90.745 | 90.745 | 90.745 | 88.68 | 88.68 | 88.68 | 88.68 | 88.68 | 88.68 |
| | solid | | | | | | | | | | | |
| | content | | | | | | | | | | | |
| Evaluation | Developability | A | A | A | B | D | A | A | A | A | A | B |
| | Post-exposure | D | C | C | C | A | D | D | C | C | C | C |
| | color | | | | | | | | | | | |
| | developability | | | | | | | | | | | |
| | Support film | A | A | C | C | D | A | A | C | A | C | C |
| | colorability | | | | | | | | | | | |

TABLE 7

| | | | | | Comp. | | | | | Comp. |
|---|---|---|---|---|---|---|---|---|---|---|
| | | Ex. 31 | Ex. 32 | Ex. 33 | Ex. 1 | Ex. 34 | Ex. 35 | Ex. 36 | Ex. 37 | Ex. 2 |
| | | Cmp. 31 | Cmp. 32 | Cmp. 33 | Cmp. 34 | Cmp. 35 | Cmp. 36 | Cmp. 37 | Cmp. 38 | Cmp. 39 |
| (A) Alkali-soluble | A-25 | 73 | | | | | | | | |
| polymer | A-26 | | 73 | 73 | 73 | | | | | 73 |
| | A-27 | 50 | 50 | | | | | | | |
| | A-29 | | | 50 | | | | | | |
| | A-30 | | | | 50 | | | | | 50 |
| | A-31 | | | | | 112 | | | | |
| | A-32 | | | | | | 112 | | | |
| | A-33 | | | | | | | 112 | | |
| | A-34 | | | | | | | | 112 | |
| (B) Monomer | B-3 | 20 | 20 | 20 | 20 | 20 | 20 | 20 | 20 | 20 |
| | B-4 | 15 | 15 | 15 | 15 | 15 | 15 | 15 | 15 | 15 |
| (C) | C-1 | 3 | 3 | 3 | 3 | 3 | 3 | 3 | 3 | 3 |
| Photopolymerization | | | | | | | | | | |
| initiator | C-3 | 0.2 | 0.2 | 0.2 | 0.2 | 0.2 | 0.2 | 0.2 | 0.2 | 0.2 |
| (D) Peroxide | D-1 (ppm) | 0 | 0 | 0 | 0 | 0 | 0 | 0 | 0 | 0 |
| | D-2 (ppm) | 214 | 659 | 856 | 1,008 | 10 | 152 | 316 | 962 | 0 |
| | Total amount of peroxide | 214 | 659 | 856 | 1,008 | 10 | 152 | 316 | 962 | 0 |
| (G) Colorant | G-1 | 0.5 | 0.5 | 0.5 | 0.5 | 0.5 | 0.5 | 0.5 | 0.5 | 0.5 |
| | G-2 | 0.05 | 0.05 | 0.05 | 0.05 | 0.05 | 0.05 | 0.05 | 0.05 | 0.05 |
| Solvent | MEK | 15 | 15 | 15 | 15 | 15 | 15 | 15 | 15 | 15 |
| | Total solid content | 88.68 | 88.68 | 88.68 | 88.68 | 88.59 | 88.59 | 88.59 | 88.59 | 88.68 |
| Evaluation | Developability | A | C | D | E | A | A | B | D | A |
| | Post-exposure color | C | B | A | A | D | C | C | A | E |
| | developability | | | | | | | | | |
| | Support film colorability | C | C | D | D | A | C | C | D | A |

TABLE 8

| | | Ex. 38 | Ex. 39 | Ex. 40 |
|---|---|---|---|---|
| | | Cmp. 40 | Cmp. 41 | Cmp. 42 |
| (A) Alkali-soluble | A-26 | 73 | 73 | 73 |
| polymer | A-27 | 50 | 50 | 50 |
| (B) Monomer | B-3 | 20 | 20 | 20 |
| | B-4 | 15 | 15 | 15 |
| (C) | C-1 | 3 | 3 | 3 |
| Photopolymerization | C-3 | 0.2 | 0.2 | 0.2 |
| initiator | | | | |
| (D) Peroxide | D-1 (ppm) | 0 | 0 | 0 |
| | D-2 (ppm) | 659 | 659 | 659 |
| | Total amount of peroxide | 659 | 659 | 659 |
| (G) Colorant | G-1 | 0.5 | 0.5 | 0.5 |
| | G-2 | 0.05 | 0.05 | 0.05 |
| (H) Radical | H-1 | 0.005 | | |
| polymerization inhibitor | | | | |
| Solvent | MEK | 15 | 15 | 15 |
| | Total solid content | 88.68 | 88.68 | 88.68 |
| Evaluation | Developability | C | C | C |
| | Post-exposure color | D | B | B |
| | developability | | | |
| | Support film colorability | C | C | C |

### INDUSTRIAL APPLICABILITY

The photosensitive resin multilayer body of the present disclosure has high sensitivity and high resolution. Therefore, the photosensitive resin multilayer body of the present disclosure can be suitably used for the production of a conductor pattern in circuit boards (printed wiring boards), flexible boards, lead frame boards, chip on film (COF) boards, semiconductor package boards, transparent electrodes for liquid crystal panels, TFT wiring for liquid crystal panels, wirings for organic EL displays, plasma display panel (PDP) electrodes and the like.

1. A photosensitive resin multilayer body comprising a support film, and a photosensitive resin composition layer formed on the support film, wherein the photosensitive resin composition layer comprises:
an alkali-soluble polymer,
a compound having at least one ethylenically unsaturated double bond,
a photopolymerization initiator, and
a peroxide containing acetone peroxide and/or methyl ethyl ketone peroxide, and
the content of the peroxide in the photosensitive resin composition layer is 0.01 ppm or more and 1,000 ppm or less, based on the photosensitive resin composition layer.

2. The photosensitive resin multilayer body according to claim 1, wherein the content of the peroxide in the photosensitive resin composition layer is 0.1 ppm or more, based on the photosensitive resin composition layer.

3. The photosensitive resin multilayer body according to claim 1, wherein the content of the peroxide in the photosensitive resin composition layer is 1 ppm or more, based on the photosensitive resin composition layer.

4. The photosensitive resin multilayer body according to claim 1, wherein the content of the peroxide in the photosensitive resin composition layer is 10 ppm or more, based on the photosensitive resin composition layer.

5. The photosensitive resin multilayer body according to claim 1, wherein the content of the peroxide in the photosensitive resin composition layer is 200 ppm or less, based on the photosensitive resin composition layer.

6. The photosensitive resin multilayer body according to claim 1, wherein the content of the peroxide in the photosensitive resin composition layer is less than 100 ppm based on the photosensitive resin composition layer.

7. The photosensitive resin multilayer body according to claim 1, wherein the content of the peroxide in the photosensitive resin composition layer is 10 ppm or less, based on the photosensitive resin composition layer.

8. The photosensitive resin multilayer body according to claim 1, wherein the content of the peroxide in the photosensitive resin composition layer is 5 ppm or less, based on the photosensitive resin composition layer.

9. The photosensitive resin multilayer body according to claim 1, wherein the content of the peroxide in the photosensitive resin composition layer is 1 ppm or less, based on the photosensitive resin composition layer.

10. The photosensitive resin multilayer body according to claim 1, wherein the alkali-soluble polymer comprises a copolymer including an aromatic component as a monomer unit.

11. The photosensitive resin multilayer body according to claim 1, wherein the compound having at least one ethylenically unsaturated double bond contains a monomer having three or four (meth)acryloyl groups.

12. The photosensitive resin multilayer body according to claim 1, wherein the photosensitive resin composition layer further comprises a colorant, and the colorant comprises 0.01 parts by weight to 1 part by weight of a dye and 0 parts by weight to 0.01 parts by weight of a pigment based on 100 parts by weight of the alkali-soluble polymer.

13. The photosensitive resin multilayer body according to claim 12, wherein the dye comprises Leuco Crystal Violet and/or Diamond Green.

14. The photosensitive resin multilayer body according to claim 1, wherein the photosensitive resin composition layer further comprises a radical polymerization inhibitor.

15. The photosensitive resin multilayer body according to claim 1, wherein the photosensitive resin composition layer comprises a colorant, and an oxide and/or a decomposition product of the colorant.

16. The photosensitive resin multilayer body according to claim 15, comprising, as the oxide and/or the decomposition product of the colorant, 4-dimethylaminophenol and/or 4-diethylaminophenol.

17. A method for producing a photosensitive resin multilayer body comprising a support film, and a photosensitive resin composition layer formed on the support film, the method comprising:
a step of preparing a coating solution comprising:
an alkali-soluble polymer,
a compound having at least one ethylenically unsaturated double bond,
a photopolymerization initiator, and
a peroxide containing acetone peroxide and/or methyl ethyl ketone peroxide, and
a step of applying the coating solution on the support film and drying the coating solution to form the photosensitive resin composition layer, wherein
the content of the peroxide in the photosensitive resin composition layer thus formed is 0.01 ppm or more and 1,000 ppm or less, based on the photosensitive resin composition layer.

18. The method for producing a photosensitive resin multilayer body according to claim 17, wherein the content of the peroxide in the photosensitive resin composition layer is 0.01 ppm or more and less than 100 ppm based on the photosensitive resin composition layer.

19. A photosensitive resin multilayer body comprising a support film, and a photosensitive resin composition layer formed on the support film, wherein the photosensitive resin composition layer comprises:
an alkali-soluble polymer,
a compound having at least one ethylenically unsaturated double bond,
a photopolymerization initiator,
a colorant,
an oxide and/or a decomposition product of the colorant, and
a radical polymerization inhibitor.

20. The photosensitive resin multilayer body according to claim 19, comprising, as the oxide and/or the decomposition product of the colorant, 4-dimethylaminophenol and/or 4-diethylaminophenol.
